(19) United States
(12) Patent Application Publication
(10) Pub. No.: US 2025/0246587 A1
(43) Pub. Date: Jul. 31, 2025

(54) ELECTRONIC DEVICE

(71) Applicant: Advanced Semiconductor Engineering, Inc., Kaohsiung (TW)

(72) Inventors: Cheng-Ting CHEN, Kaohsiung (TW); Hai-Ming CHEN, Kaohsiung (TW); Hung-Yi LIN, Kaohsiung (TW)

(73) Assignee: Advanced Semiconductor Engineering, Inc., Kaohsiung (TW)

(21) Appl. No.: 18/791,348

(22) Filed: Jul. 31, 2024

Related U.S. Application Data
(63) Continuation-in-part of application No. 18/429,116, filed on Jan. 31, 2024.

(51) Int. Cl. H01L 25/16; G02B 6/12; H01L 23/00; H01L 23/31; H01L 23/36; H01L 23/538; H10B 80/00

(52) U.S. Cl. CPC H01L 25/167; G02B 6/12004; H01L 23/36; H01L 23/5385; H01L 23/3107; H01L 24/08; H01L 24/16; H01L 24/17; H01L 24/32; H01L 24/73; H01L 2224/08225; H01L 2224/16145; H01L 2224/16225; H01L 2224/17181; H01L 2224/32225; H01L 2224/73204; H01L 2224/73253; H10B 80/00

(57) ABSTRACT

An electronic device is provided. The electronic device includes a plurality of processing units constituting a processing array having a first area, a surface supporting the processing array, and an optical channel. The surface has a second area, and the first area is greater than 80 percent of the second area. The optical channel is configured to transmit a first signal between at least two of the plurality of processing units in a first direction that is nonparallel with a normal direction of the surface.

### CROSS-REFERENCE TO RELATED APPLICATION

This application is a continuation-in-part of U.S. patent application Ser. No. 18/429,116, filed Jan. 31, 2024, the content of which is incorporate herein by reference in its entirety.

### BACKGROUND

### 1. Technical Field

The present disclosure relates generally to an electronic device.

### 2. Description of the Related Art

Currently, data transmission between dies in a large sized package is achieved by a multi-layered redistribution layer (RDL). However, long-distance data transmission between the dies suffers from serious signal attenuation and power consumption. Therefore, there is a need for improving the efficiency of long-distance data transmission between the dies in a large sized package.

### SUMMARY

In one or more arrangements, an electronic device includes a plurality of processing units constituting a processing array having a first area, a surface supporting the processing array, and an optical channel. The surface has a second area, and the first area is greater than 80 percent of the second area. The optical channel is configured to transmit a first signal between at least two of the plurality of processing units in a first direction that is nonparallel with a normal direction of the surface.

In one or more arrangements, an electronic device includes a plurality of processing units, a plurality of power units, and an optical channel. The processing units are supported by a first surface. The power units are supported by a second surface distinct from the first surface and configured to provide power to the processing units. The optical channel is configured to transmit a first signal between at least two of the plurality of processing units.

In one or more arrangements, an electronic device includes a plurality of processing units, a plurality of power units, and an optical channel. The power units are configured to provide power to the corresponding processing units. The optical channel is configured to transmit a first signal between at least two of the plurality of processing units. An arrangement density of the plurality of processing units is different from an arrangement density of the plurality of power units.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of an electronic device in accordance with some arrangements of the present disclosure.

FIG. 1B is a top view of an electronic device in accordance with some arrangements of the present disclosure.

FIG. 2A is a cross-section of an electronic device in accordance with some arrangements of the present disclosure.

FIG. 2B is a top view of an electronic device in accordance with some arrangements of the present disclosure.

FIG. 2C is a top view of an electronic device in accordance with some arrangements of the present disclosure.

FIG. 3A is a cross-section of an electronic device in accordance with some arrangements of the present disclosure.

FIG. 3B is a cross-section of an electronic device in accordance with some arrangements of the present disclosure.

FIG. 3C is a cross-section of an electronic device in accordance with some arrangements of the present disclosure.

FIG. 3D is a cross-section of an electronic device in accordance with some arrangements of the present disclosure.

FIG. 4A is a cross-section of an electronic device in accordance with some arrangements of the present disclosure.

FIG. 4B is a top view of an electronic device in accordance with some arrangements of the present disclosure.

FIG. 5 is a cross-section of an electronic device in accordance with some arrangements of the present disclosure.

FIG. 6A, FIG. 6B, FIG. 6C, FIG. 6D, FIG. 6E, FIG. 6F, FIG. 6G, FIG. 6H, and FIG. 6I illustrate various stages of an exemplary method for manufacturing an electronic device in accordance with some embodiments of the present disclosure.

FIG. 7A, FIG. 7B, FIG. 7C, FIG. 7D, FIG. 7E, FIG. 7F, FIG. 7G, FIG. 7H, and FIG. 7I illustrate various stages of an exemplary method for manufacturing an electronic device in accordance with some embodiments of the present disclosure.

FIG. 8A, FIG. 8B, FIG. 8C, FIG. 8D, FIG. 8E, FIG. 8F, and FIG. 8G illustrate various stages of an exemplary method for manufacturing an electronic device in accordance with some embodiments of the present disclosure.

FIG. 9A is a cross-section of an electronic device in accordance with some arrangements of the present disclosure.

FIG. 9B is a top view of an electronic device in accordance with some arrangements of the present disclosure.

FIG. 9B-1 is a top view of an electronic device in accordance with some arrangements of the present disclosure.

FIG. 9C is a cross-section of an electronic device in accordance with some arrangements of the present disclosure.

FIG. 9D is a cross-section of an electronic device in accordance with some arrangements of the present disclosure.

FIG. 10A is a cross-section of an electronic device in accordance with some arrangements of the present disclosure.

FIG. 10B is a cross-section of an electronic device in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

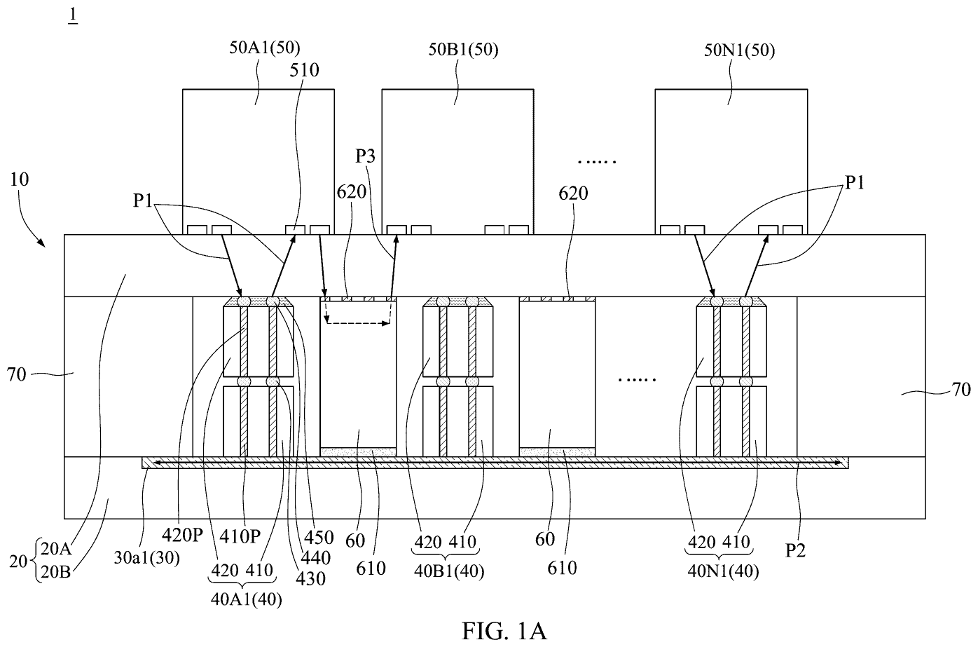

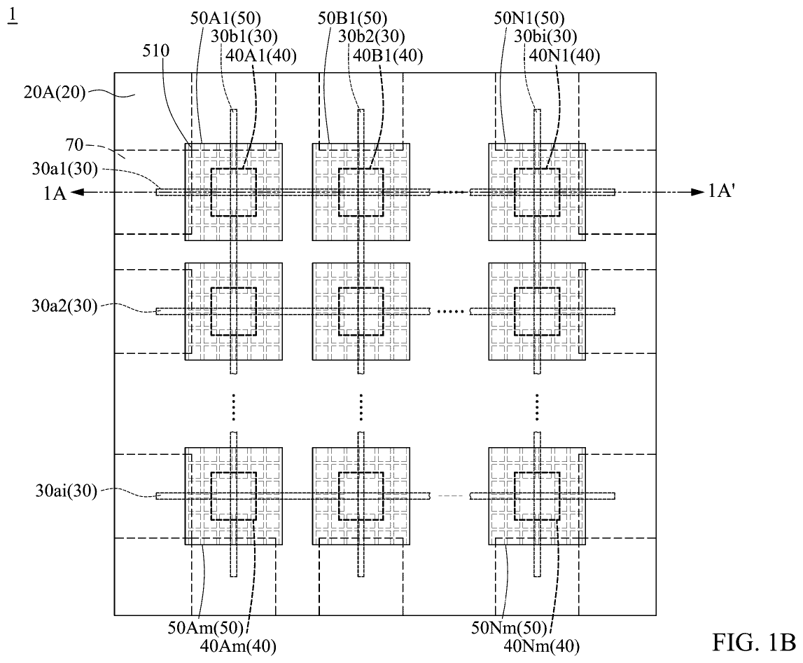

FIG. 1A is a cross-section of an electronic device 1 in accordance with some arrangements of the present disclosure. The electronic device 1 may include a circuit structure 10, optical engines 40, electronic components 50, bridge components 60, and photonic components 70. In some arrangements, the electronic device 1 may be or include an extreme large scale panel (ELSP). The electronic device 1 may be or include a data center including a great number of processing components (or processing units) with relatively long distances between the processing components (or the processing units).

The circuit structure 10 may support the electronic components 50. In some arrangements, the circuit structure 10 is configured to provide electrical communication (or electrical transmission) and optical communication (or optical transmission) between at least two or more of the electronic components 50. In some arrangements, the circuit structure 10 is configured to provide electrical communication between the electronic components 50 along one or more transmission paths P1 and to provide optical communication between the electronic components 50 along a transmission path P2. In some arrangements, the circuit structure 10 is further configured to provide electrical communication between the electronic components 50 along one or more transmission paths P3 different from the transmission paths P1. In some arrangements, the transmission path P2 is longer than the transmission path P1. In some arrangements, the transmission path P2 is longer than the transmission path P3. In some arrangements, the transmission path P2 is greater than about 10 mm. In some arrangements, the transmission path P1 and the transmission path P2 extend in different directions. In some arrangements, the transmission path P3 and the transmission path P2 extend in different directions. In some arrangements, the transmission path P1 is substantially perpendicular to the transmission path P2. In some arrangements, the transmission path P3 is substantially perpendicular to the transmission path P2. In some arrangements, the transmission paths P1 and P3 may be referred to as vertical paths, and the transmission path P2 may be referred to as a horizontal path. In some arrangements, at least a portion of the transmission path P3 is substantially parallel to the transmission path P2. In some arrangements, the transmission paths P1 and P3 may be referred to as electrical paths or electrical communication paths, and the transmission path P2 may be referred to as an optical path or an optical communication path. In some arrangements, the circuit structure 10 is configured to connect the adjacent electronic components 50 along the transmission path P3, and the circuit structure 10 is further configured to connect the electronic components 50 that are not adjacent to each other along the transmission path P2 having a greater length and a lower power consumption per unit length than the transmission path P3. The term “power consumption per unit length” used hereinafter indicates a consumption amount of power transmitted by a unit length of the transmission path, which may be also referred to as a power consumption rate. The term “power consumption” used hereinafter indicates a consumption amount of power between terminals, such as electronic components, electrodes/terminals of electronic components, and a terminal of the circuit structure and a terminal of the electronic component. In some arrangements, the short communication path (i.e., the transmission paths P1 and P3) between the adjacent electronic components 50 may be a millimeter (mm) level, and can be implemented by an electrical path. The longer communication path (such as the transmission path P2) between electronic components 50 may be under a centimeter (cm) or meter (m) level, and can be implemented by an electrical path or an optical path. The optical path can provide a lower power consumption per unit length than the electrical path. In some arrangements, although the transmission path P2 has a lower power consumption per unit length, the total power consumption of the transmission path P2 may be greater than that of the transmission path P1, P3 due to the greater length. For example, the length of the transmission path P3 connecting the adjacent electronic components 50 may be a millimeter (mm) level, and the power consumption of the transmission path P3 may be about 0.5pJ/bit. The length of the transmission path P2 connecting the electronic components 50 may be a centimeter (cm) or meter (m) level, and the power consumption of the transmission path P2 may be about 2pJ/bit.

In some arrangements, the circuit structure 10 is configured to connect the adjacent electronic components 50 along the transmission path P3, and the circuit structure 10 is further configured to connect the electronic components 50 that are not adjacent to each other along the transmission path P2 having a greater length and a higher speed than the transmission path P3. When the transmission distance is the same, the signal attenuation and loss of the optical transmission (such as optical fibers) is relatively less than that of the electrical transmission (such as copper cable), since the electrical transmission is more susceptible to external interference. The speed of optical transmission is higher than that of electrical transmission. For example, the transmission rate of the optical transmission can be up to about 100 Gbps, and that of the electrical transmission can be about 40 Gbps. Therefore, the transmission path P2 can have a higher speed than the transmission path P3. In some embodiments, the speed of the transmission path P3 may be about 50% to 75% of the speed of the transmission path P2. The speed of light may be about 200,000 km/s to about 300,000 km/s depending on the optical medium (for example, the optical fibers). The speed of electricity may be about 150,000 km/s to 297,000 km/s depending on the arrangements and elements beside the electrical transmission.

In some arrangements, the circuit structure 10 includes circuits 20A, 20B, and 30. The circuits 20A and 20B may be referred to as circuit layers, redistribution layers (RDLs), or the like. In some arrangements, the circuits 20A and 20B may be collectively referred to as a circuit 20. The circuit 30 may be referred to as an optical waveguide, an optical channel, or the like.

In some arrangements, the circuit 20A is disposed between the circuit 30 and the electronic components 50 and configured to connect at least two of the electronic components 50 along the transmission path P1 and/or the transmission path P3. The circuit 20A may include a dielectric layer and a conductive structure (not shown in FIG. 1A) formed in the dielectric layer. The conductive structure may include an interconnection structure (e.g., a redistribution layer (RDL)), which may include such as a plurality of conductive traces and/or a plurality of conductive vias. The interconnection structure may be or include circuit layers. In some arrangements, the transmission path P1 passes a portion of the conductive structure of the circuit 20A to electrically connect to the electronic component 50 to provide electrical communication or electrical connection. In some arrangements, the transmission path P3 passes a portion of the conductive structure of the circuit 20A to electrically connect to the electronic component 50 to provide electrical communication or electrical connection.

In some arrangements, the circuit 30 (or the optical channel) is configured to connect the electronic components 50 along the transmission path P2. In some arrangements, the circuit 30 vertically overlaps two or more of the electronic components 50. In some arrangements, the circuit 30 includes an optical channel. In some arrangements, the circuit 30 includes an optical waveguide. The circuit 30 may be formed of or include an optical waveguide material, e.g., a polymer material (e.g., a polymer waveguide), silicon nitride, silicon oxide, or other suitable materials. In some arrangements, the circuit 30 includes one or more optical fibers. In some arrangements, the circuit 30 includes a glass substrate including glass modification lines having a refractive index higher than that of the glass substrate and serving as the optical channel. In some arrangements, the transmission path P2 passes a portion of the circuit 30 (or the optical waveguide) to provide optical communication or optical connection. In some arrangements, the transmission path P2 and the transmission path P3 are at different elevations. In some arrangements, the transmission path P3 is closer to the electronic components 50 than the transmission path P2 is.

The circuit 20B may support the optical engines 40. In some arrangements, the optical engines 40 are disposed between the circuit 20A and the circuit 20B. The circuit 20B may include a dielectric layer and a conductive structure (not shown in FIG. 1A) formed in the dielectric layer. The conductive structure may include an interconnection structure (e.g., a RDL), which may include such as a plurality of conductive traces and/or a plurality of conductive vias. The interconnection structure may be or include circuit layers. In some arrangements, the circuit 30 may be formed in the dielectric layer of the circuit 20B. In some arrangements, a top surface of the circuit 30 may be substantially coplanar or aligned with a top surface of the circuit 20B. In some arrangements, the circuit 20B may be replaced by a substrate without any conductive structure formed therein, and the substrate is configured to support the components/element there above.

The optical engines 40 may be disposed on the circuit 30. In some arrangements, the optical engine 40 includes a transducer 410 (or a photonic element or a photonic component) and an electronic element 420 (or an electronic component). In some arrangements, the optical engine 40 further includes connection elements 430 and 440 and a protective layer 450. In some arrangements, the transducer 410 is connected (e.g., electrically connected) to the electronic element 420 through the connection elements 430, and the electronic element 420 is connected (e.g., electrically connected) to the circuit 20A through the connection elements 440. In some arrangements, the protective layer 450 encapsulates the connection elements 440. The protective layer 450 may be or include an underfill. In some arrangements, the transducer 410 is or includes a photonic component, e.g., a photonic integrated circuit (PIC), and the electronic element 420 is or includes an electronic component, e.g., an electronic integrated circuit (EIC). In some arrangements, the optical engines 40 are or include photonic components. In some arrangements, there are N optical engines 40A1 to 40N1 in a row, and each of the optical engines 40A1 to 40N1 is disposed under a corresponding one of the electronic components 50A1 to 50N1. N may be equal to or greater than 6, 10, 15, 20, or 25. In some arrangements, a distance between the electronic component 50A1 and the electronic component 50N1 may be about 0.35 meters or greater, for example, 1 meter or greater.

In some arrangements, the transducer 410 is configured to provide a photoelectric conversion and electrically connecting the circuit structure 10 to one or more of the electronic components 50. In some arrangements, the transducer 410 is disposed between the circuit 30 (or the optical channel) and the electronic components 50. In some arrangements, the transducer 410 is disposed between the circuit 30 and the circuit 20A and configured to provide a photoelectric conversion. In some arrangements, the transducer 410 is configured to communicate optical signals (or modulated optical signals). For example, the transducer 410 may be configured to transmit or receive optical signals. In some embodiments, the transducer 410 includes an optical component (e.g., a waveguide) configured to transmit optical signals (e.g., light), for example, received from a laser diode, an optical fiber, or an optical fiber array. In some arrangements, the transducer 410 includes a photonic integrated circuit (PIC) or a photonic die. In some embodiments, the transducer 410 may include a laser diode, a receiver, a waveguide, a photodetector, a photodiode, a semiconductor optical amplifier (SOA), a grating coupler, a fiber coupling structure, an optical modulator (e.g., Mach-Zehnder modulator or microring modulator), or a combination thereof. For example, the transducer 410 may include a combination of photonic devices in a circuit and other active and passive optical devices on a single substrate to achieve a desired function. In some arrangements, the transducer 410 includes pillars 410P extending between a top surface and a bottom surface of the transducer 410. The pillars 410P may include one or more electrically conductive pillars configured to transmit electrical signals and one or more optical pillars configured to transmit optical signals. The pillars 410P may be or include through silicon vias (TSVs).

In some arrangements, the electronic element 420 is disposed between the circuit 30 and the circuit 20A and connected to the transducer 410. In some arrangements, the electronic element 420 is closer to the electronic components 50 than the transducer 410 is. In some arrangements, the electronic element 420 is configured to control modulation of optical signals. In some arrangements, the electronic element 420 is configured to amplify electrical signals. In some arrangements, the electronic element 420 includes multiple devices configured to control modulation of optical signals and configured to amplify electrical signals, respectively. In some arrangements, the electronic element 420 is configured to control an optical modulator. In some arrangements, the electronic element 420 is configured to amplify electrical signals received from the transducer 410, for example, a photodetector of the transducer 410. In some arrangements, the photodetector is configured to convert optical signals to electrical signals. In some arrangements, the electronic element 420 may include a modulator driver (DRV), a trans-impedance amplifier (TIA), or a combination thereof. In some arrangements, the electronic element 420 may include one or more active devices, one or more passive circuit components, and electrically conductive paths interconnecting the active devices and the passive circuit components in electrical circuit relationships for performing a desired sub-circuit control function. In some arrangements, the electronic element 420 includes pillars 420P extending between a top surface and a bottom surface of the electronic element 420. The pillars 420P may include one or more electrically conductive pillars configured to transmit electrical signals. The pillars 420P may be or include through silicon vias (TSVs).

The electronic components 50 may be supported by the circuit structure 10. The electronic component 50 may include terminals 510 configured to electrically connect to the circuit 20A. In some arrangements, there are N electronic components 50A1 to 50N1 in a row over the circuit 20A. N may be equal to or greater than 6, 10, 15, 20, or 25. In some arrangements, the terminals 510 may be or include conductive pads adjacent to or under a surface (e.g., a bottom surface) of the electronic component 50. In some arrangements, the terminals 510 may be or include conductive pads embedded in and exposed from a surface (e.g., a bottom surface) of the electronic component 50. In some arrangements, the terminals 510 are arranged in an array on or adjacent to a surface (e.g., a bottom surface) of the electronic component 50. In some arrangements, the terminals 510 of the electronic component 50 may use a Universal Chiplet Interconnect express” (UCIe) interconnect protocol to connect the electronic components 50 in the electronic device 1. In some arrangements, the terminals 510 of the electronic component 50 may use an UCIe interconnect protocol to connect the electronic components 50 of the electronic device 1 to devices external to the electronic device 1. In some arrangements, the terminals 510 may replace one or more discrete input/output (I/O) components or I/O dies that are disposed side-by-side with the electronic components 50 in the electronic device 1.

According to some arrangements of the present disclosure, the terminals 510 adjacent to or under the bottom surface of the electronic component 50 may serve as I/O components of the electronic device 1, thus discrete I/O components or I/O dies can be omitted. Therefore, the device area occupied by the discrete I/O components or I/O dies can be reduced, the volume of the electronic device 1 can be reduced, and the cost can be reduced as well. In addition, the terminals 510 are arranged in an array on or adjacent to the bottom surface of the electronic component 50 instead of utilizing discrete I/O components or I/O dies, off-chip bandwidth can be increased significantly. Moreover, the terminals 510 adopt a Wide I/O interface instead of SerDes interface, such that the power consumption for transmission between the electronic components 50 for a distance of about 50 cm can be reduced from about 25 pJ/bit to about 2 pJ/bit or even about 0.5 pJ/bit.

In some arrangements, the electronic components 50 may include electronic components 50A1 to 50N1. In some arrangements, the electronic components 50 may include an electronic component 50A1, an electronic component 50B1 adjacent to the electronic component 50A1, and an electronic component 50N1 distal from the electronic components 50A1 and 50B1. In some arrangements, a distance between the electronic component 50A1 and the electronic component 50B1 is less than a distance between the electronic component 50A1 and the electronic component 50N1. The electronic components 50 may include processing components or processing units. In some arrangements, the electronic components 50A1 to 50N1 may independently include an ASIC, an FPGA, a GPU, or the like, or a combination thereof. In some arrangements, the electronic components 50A1 to 50N1 may independently include a processing unit, such as a processing core or a processing chiplet.

In some arrangements, the electronic component 50A1 is connected to the electronic component 50B1 through the electrical communication (or the electrical transmission) provided by the circuit structure 10. In some arrangements, the circuit structure 10 is configured to provide the electrical communication (or the electrical transmission) between the adjacent electronic components (e.g., the electronic component 50A1 and the electronic component 50B1) along the transmission path P3.

In some arrangements, the electronic component 50A1 is connected to the electronic component 50N1 through the optical communication (or the optical transmission) provided by the circuit structure 10. In some arrangements, the electronic component 50A1 is connected to the electronic component 50N1 through a combination of the electrical communication (or the electrical transmission) and the optical communication (or the optical transmission) provided by the circuit structure 10. In some arrangements, the circuit structure 10 is configured to provide the optical communication (or the optical transmission) between the electronic component 50A1 and the electronic component 50N1 along the transmission path P2. In some arrangements, the circuit structure 10 is configured to provide the electrical communication (or the electrical transmission) between the electronic component 50A1 and the electronic component 50N1 along the transmission paths P1. In some arrangements, an electrical signal from the electronic component 50A1 may be received by the optical engine 40A1 through the transmission path P1, the electrical signal may be converted into an optical signal by the optical engine 40A1, and then the optical signal may be transmitted to the optical engine 40N1 under the electronic component 50N1 through the transmission path P2 and converted into an electrical signal, which then is transmitted to the electronic component 50N1 through the transmission path P1.

The bridge components 60 may be disposed between the circuit 30 and the circuit 20A. In some arrangements, the bridge component 60 is configured to electrically connect at least one of the electronic components 50 through the circuit 20A along the transmission path P3. In some arrangements, the bridge component 60 vertically overlaps a gap between adjacent electronic components 50 (e.g., a gap between the electronic component 50A1 and the electronic component 50B1). In some arrangements, the bridge component 60 does not contact the circuit 30. In some arrangements, the bridge component 60 is not at the transmission path P3. In some arrangements, the bridge component 60 is adhered to the circuit 20B through an adhesive layer 610. The adhesive layer 610 may be or include a die attach film (DAF). In some arrangements, the bridge component 60 includes connection elements 620 electrically connected to the circuit 20A.

In some arrangements, the circuit structure 10, the optical engines 40, and the bridge components 60 collectively construct an optoelectronic interposer. The optoelectronic interposer may be configured to communicate the electronic components 50 separated by a relatively long distance by a combination of electrical transmission and optical transmission. In some arrangements, the optoelectronic interposer includes a circuit 20A (or an RDL), a circuit 30 (or an optical waveguide), optical engines 40, and bridge components 60. In some arrangements, the optoelectronic interposer is disposed at a side (a first side or an upper side) of the electronic components 50 and configured to provide electrical transmission (or electrical communication) and optical transmission (or optical communication) between the electronic components 50. In some arrangements, the optoelectronic interposer includes photonic components (e.g., the optical engines 40) and an optical channel (e.g., the circuit 30) connecting the photonic components. In some arrangements, the optical channel (e.g., the circuit 30) is configured to connect to an optical component external to the electronic device 1.

The photonic component 70 may be disposed between the circuit 30 and the circuit 20A and optically coupled to the circuit 30. In some arrangements, the photonic component 70 is configured to transmit an optical signal to the circuit 30. In some arrangements, the photonic component 70 is configured to receive an optical signal from the circuit 30. In some arrangements, the photonic component 70 is further configured to provide a photoelectric conversion and electrically connected to the circuit 20A. In some arrangements, the photonic component 70 is configured to convert an optical signal to an electrical signal and then transmit the electrical signal to the circuit 20A. In some arrangements, the photonic component 70 is configured to receive an electrical signal from the circuit 20A and convert the electrical signal to an optical signal.

FIG. 1B is a top view of an electronic device 1 in accordance with some arrangements of the present disclosure. In some arrangements, FIG. 1A shows a cross-section along a line 1A-1A′ in FIG. 1B.

In some arrangements, the electronic device 1 includes an array of electronic components 50 arranged in columns and rows and an array of optical engines 40 arranged in columns and rows. In some arrangements, there are N columns and m rows in the arrays. In some arrangements, referring to FIG. 1A, the electronic component 50A1 may be connected to the electronic component 50Nm through electrical communication by the transmission paths P1 and optical communication by the transmission paths P2. In some arrangements, the optical communication between the electronic component 50A1 and the electronic component 50Nm involves a photoelectric conversion performed by the optical engine 40A1 to covert an electrical signal to an optical signal, transmitting the optical signal by the circuit 30 from the optical engine 40A1 to the optical engine 40Mn, and a photoelectric conversion performed by the optical engine 40Nm to covert the optical signal to an electrical signal. In some arrangements, referring to FIG. 1A, the electronic component 50Am may be connected to the electronic component 50N1 through electrical communication by the transmission paths P1 and optical communication by the transmission paths P2. In some arrangements, the optical communication between the electronic component 50Am and the electronic component 50N1 involves a photoelectric conversion performed by the optical engine 40Am to covert an electrical signal to an optical signal, transmitting the optical signal by the circuit 30 from the optical engine 40Am to the optical engine 40N1, and a photoelectric conversion performed by the optical engine 40N1 to covert the optical signal to an electrical signal.

In some arrangements, the circuit 30 includes an optical mesh network. In some arrangements, the circuit 30 includes a grid structure. In some arrangements, the circuit 30 includes a single-layered grid structure. In some arrangements, the optoelectronic interposer includes an optical waveguide network (e.g., the circuit 30) for the optical transmission or optical communication. In some arrangements, the circuit 30 includes an optical waveguide network (or an optical grid structure) including a plurality of waveguides 30al to 30ai and a plurality of waveguides 30b1 to 30bi crossing the waveguides 30al to 30ai. In some arrangements, the intersections of the waveguides are disposed under the optical engines 40. In some arrangements, the intersections are formed of two waveguides crossing-over and stacked on each other. The network of intersections formed from crossed-over and stacked waveguides may be referred to as an optical mesh network. In some arrangements, the intersections are formed of waveguides directly connected to each other and/or formed integrally in a single layer. The network of intersections formed in a single layer may be referred to as a single-layered optical grid structure. In some arrangements, each of the intersections of the waveguides 30a1 to 30ai and the waveguides 30b1 to 30bi is disposed under and optically coupled to a corresponding one of the optical engines 40 to receive an optical signal from or transmit an optical signal to the corresponding one of the optical engines 40.

In some cases when long distance communication between electronic components is required in a relatively large device or package, signal transmission by electrical paths (e.g., RDLs, fan-out structures, or the like) may suffer from large power loss and high latency. To solve the issue of large power loss, a higher power may be supplied at the beginning of the electrical paths; however, power consumption is increased accordingly. In contrast, according to some arrangements of the present disclosure, with the design of integration of long distance transmission by optical paths (e.g., the transmission path P2) and short distance transmission by electrical paths (e.g., the transmission paths P1 and P3), since power loss by optical transmission is relatively low, signal loss and power consumption of the transmission between the electronic components 50 adopting the aforementioned combination of long distance optical transmission and short distance electrical transmission can be reduced significantly, and thus the performance of the electronic device 1 can be improved.

In addition, according to some arrangements of the present disclosure, with the design of the optoelectronic interposer including an RDL of the circuit 20 (or the circuit 20A), the optical mesh network of the circuit 30, and the transducers 410 (or the optical engines 40) arranged corresponding to the network of the circuit 30, a large number of the electronic components 50 can be arranged in an array with the respective transducers 410 (or the respective optical engines 40) disposed corresponding to the respective electronic components 50. Therefore, despite that the electronic components 50 occupy a relatively large device area, the combination of short distance electrical transmission by electrical paths and long distance optical transmission by optical paths between the electronic components 50 can be accomplished by the optoelectronic interposer with low power loss and low latency.

Furthermore, according to some arrangements of the present disclosure, with the design of the photoelectric conversion element (the transducer 410 or the optical engine 40) disposed directly under the corresponding electronic component 50, the transmission path P1 for the electrical transmission between the electronic component 50 and the corresponding photoelectric conversion element is defined by the vertical distance between the electronic component 50 and the photoelectric conversion element, and thus the length of electrical path can be relatively short compared to the length of the optical path between the electronic components 50 that are separated from each other by a relatively long distance. In addition, according to some arrangements of the present disclosure, the vertical distance between the electronic component 50 and the photoelectric conversion element may be defined by the thickness of the circuit 20A, which is an RDL with at most two conductive layers, and thus the length of the electrical path between the electronic component 50 and the photoelectric conversion element is reduced significantly.

Moreover, according to some arrangements of the present disclosure, the transmission path P3 for the electrical communication between the adjacent electronic components 50 and the transmission path P1 for the electrical communication between the electronic component 50 and the corresponding optical engine 40 or transducer 410 both pass through portions of the circuit 20 or 20A of the circuit structure 10. Therefore, the layers or thicknesses of the electrically conductive structures for electrical communication can be reduced, which is further advantageous to reduction of the size of the electronic device 1.

Furthermore, according to some arrangements of the present disclosure, the electrical communication between the adjacent electronic components 50 can be accomplished by the transmission path P3 that passes or utilizes the bridge component 60 instead of the conductive interconnection structure within the circuit 20A. Therefore, the number of layers within the circuit 20A can be reduced, and thus the thickness of the circuit 20A can be reduced, which is advantageous to reduction of the device size. In addition, according to some arrangements of the present disclosure, the electrical communication between the adjacent electronic components 50 can be accomplished by the transmission path P3 that passes or utilizes the conductive layers of the conductive interconnection structure within the circuit 20A without passing or utilizing bridge components 60. Therefore, the space saved for the bridge components 60 can be used for disposing additional electronic components, and thus the functions and performance of the electronic device 1 can be improved.

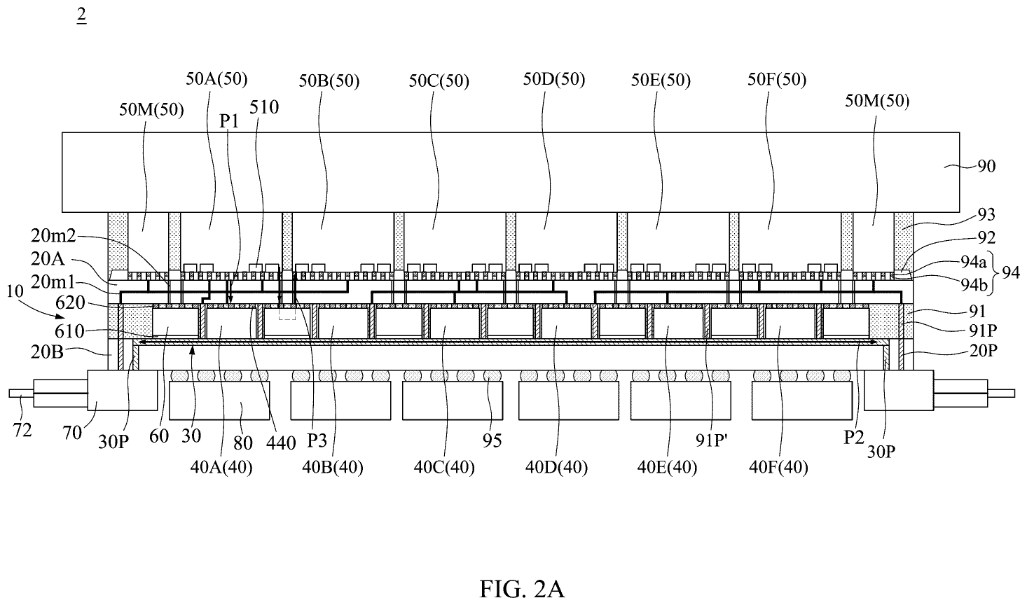

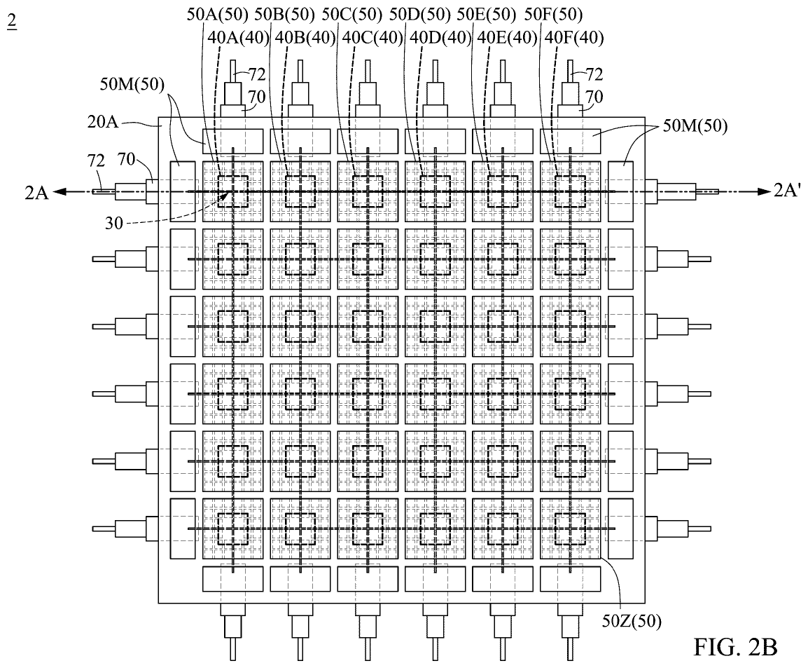

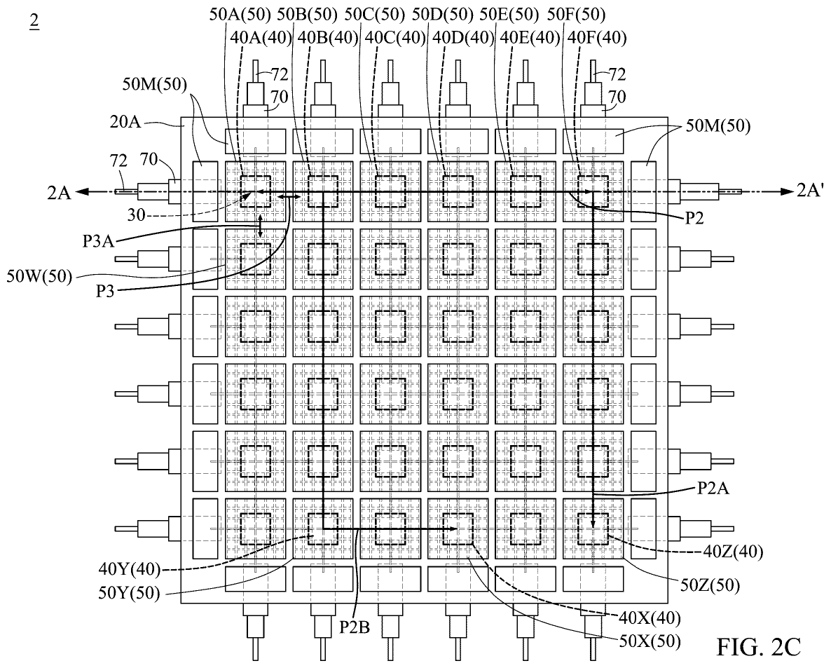

FIG. 2A is a cross-section of an electronic device 2 in accordance with some arrangements of the present disclosure. FIG. 2B is a top view of an electronic device 2 in accordance with some arrangements of the present disclosure. FIG. 2C is a top view of an electronic device 2 in accordance with some arrangements of the present disclosure. In some arrangements, FIG. 2A shows a cross-section along a line 2A-2A′ in FIG. 2B and/or in FIG. 2C. The electronic device 2 is similar to the electronic device 1 in FIG. 1A and FIG. 1B, and the differences therebetween are described as follows.

In some arrangements, the electronic device 2 further includes one or more optical components 72, power modules 80, a cooling device 90, encapsulants 91 and 93, pillars 20P, 30P, 91P, and 91P′, an underfill 92, and connection elements 94 and 95. In some arrangements, the optical engine 40 may include a structure the same as or similar to those illustrated in FIGS. 1A and 1B.

In some arrangements, the circuit 20A includes conductive structures 20m1 and 20m2. In some arrangements, the conductive structure 20m1 includes conductive traces or layers and conductive vias. The conductive structure 20m1 may be configured to provide electrical communication along the transmission paths P1. In some arrangements, the conductive structure 20m1 electrically connects the electronic component 50 to the optical engine 40. In some arrangements, the conductive structure 20m2 includes conductive pillars or conductive vias. The conductive structure 20m2 may be configured to provide electrical communication along the transmission paths P3. In some arrangements, the conductive structure 20m2 electrically connects the electronic component 50 to the bridge component 60.

In some arrangements, the pillars 20P extend between a top surface and a bottom surface of the circuit 20B. The pillars 20P, 91P, and 91P′ may be or include electrically conductive pillars. In some arrangements, the pillars 20P may be formed of or include a conductive material, e.g., metal, such as copper (Cu). In some arrangements, the pillar 20P electrically connects the pillar 91P to the photonic component 70.

In some arrangements, the pillars 30P extend between a top surface and a bottom surface of the circuit 20B. In some arrangements, the pillars 30P may be or include optical pillars. In some arrangements, the pillar 30P optically couples the circuit 30 to the photonic component 70. In some arrangements, as shown in FIG. 2B, the circuit 30 includes an optical waveguide network including crossed waveguides. In some arrangements, the circuit 30 includes an optical channel including an optical grid structure. In some arrangements, the circuit 30 (or the optical channel) is optically coupled to the photonic component (e.g., the optical engine 40) and configured to connect the electronic components 50 along the transmission path P2. In some arrangements, the circuit 20A is disposed between the optical channel (e.g., the circuit 30) and the electronic components 50 and configured to electrically connect the electronic components 50 along the transmission path P3. In some arrangements, the bridge component 60 is between the circuit 20A and the optical channel (e.g., the circuit 30) and configured to electrically connect the electronic components 50 along the transmission path P3.

The electronic components 50 may include processing components (or processing units), memory components (or memory units), or the like, or a combination thereof. In some arrangements, the electronic components 50A, 50B, 50C, 50D, 50E, and 50F may independently include an ASIC, an FPGA, a GPU, or the like, or a combination thereof. In some arrangements, the electronic components 50M may include memory components (or memory units), e.g., HBM.

The optical component 72 may be optically coupled to the photonic component 70. The optical component 72 may be configured to optically couple the electronic device 2 to a device external to the electronic device 2. In some arrangements, the optical component 72 is or includes an optical fiber array unit (FAU). In some arrangements, the electronic device 2 includes multiple optical components 72 each configured to couple a corresponding optical signal. In some arrangements, the electronic device 2 includes one optical component 72, and the circuit 20A may include a modulator circuit configured to split the optical signal into multiple optical signals with different optical properties (e.g., waveguides, polarization, or the like).

The power modules 80 (also referred to as “power units”) may be configured to provide power to the electronic components 50. In some arrangements, each of the power modules 80 is connected to a corresponding one of the electronic components 50. In some arrangements, the power modules 80 are connected to the circuit 20B through the connection elements 95. The connection elements 95 may be or include C4 bumps. In some arrangements, the circuit 20A (or the RDL) is disposed between the electronic components 50 and the power modules 80. In some arrangements, each of the power modules 80 is under and configured to provide a modulated power to each of the electronic components 50. In some arrangements, the power modules 80 are configured to provide power to the electronic components 50 through the pillars 91P′ between the bridge components 60. The power path for the modulated power may passes the circuit 20B, the pillar 91P′, and the circuit 20A. The power modules 80 may be or include voltage regulation modules (VRMs).

The cooling device 90 may be disposed over the electronic components 50. In some arrangements, the cooling device 90 contacts the electronic components 50. The cooling device 90 is configured to dissipate heat from the electronic components 50. The cooling device 90 may be or include a water-cooling device (e.g., a water cooling plate), an air-cooling device, or a combination thereof.

In some arrangements, the encapsulant 91 encapsulates the optical engines 40A, 40B, 40C, 40D, 40E, and 40F, the bridge components 60, and the pillars 91P. In some arrangements, the encapsulant 91 further encapsulates the connection elements 440 and 620 and the adhesive layers 610. In some arrangements, the pillars 91P may be formed of or include a conductive material, e.g., metal, such as copper (Cu). In some arrangements, at least one of the pillars 91P is electrically connected to the pillars 20P. In some arrangements, some of the pillars 91P may serve as thermal pipes for dissipating heat. The thermal pipes may be disposed between the optical engines 40. In some arrangements, the optoelectronic interposer (e.g., the combination of the circuit structure 10, the optical engines 40, and the bridge components 60) includes transducers that are integrated within the optical engines 40 and arranged in a same layer, and the thermal pipes (e.g., the pillars 91P) are disposed between the transducers.

In some arrangements, the connection elements 94 electrically connect the electronic components 50 to the circuit 20A, and the underfill 92 encapsulates the connection elements 94. In some arrangements, the connection elements 94 may be or include micro-bumps. Each of the connection elements 94 may include portions 94a and 94b. The portion 94a may be a conductive pad or stud, and the portion 94b may be a solder bump. In some arrangements, the encapsulant 93 encapsulates the electronic component 50A to 50F and 50M and the underfill 92.

In some arrangements, the cooling device 90 is disposed on the encapsulant 93 and contacting the exposed surfaces 501 of the electronic components 50.

In some arrangements, referring to FIG. 2C, the optical communication between the electronic components 50 can be provided by various transmission paths. In some arrangements, as shown in FIGS. 2A and 2C, the electronic component 50A may be connected to the electronic component 50F through optical communication by the transmission path P2. In some arrangements, the electronic component 50A may be connected to the electronic component 50Z through optical communication by the transmission path P2A which passes two waveguide strips of the optical grid structure (e.g., the circuit 30). In some arrangements, the transmission path P2A passes a waveguide strip between the optical engine 40A and the optical engine 40F and a waveguide strip between the optical engine 40F and the optical engine 40Z. In some arrangements, the electronic component 50A may be connected to the electronic component 50X through optical communication by the transmission path P2B which passes three waveguide strips of the optical grid structure (e.g., the circuit 30). In some arrangements, the transmission path P2B passes a waveguide strip between the optical engine 40A and the optical engine 40B, a waveguide strip between the optical engine 40B and the optical engine 40Y, and a waveguide strip between the optical engine 40Y and the optical engine 40X. In some arrangements, the electronic component 50A may be connected to the electronic component 50B through electrical communication by the transmission path P3. In some arrangements, the electronic component 50A may be connected to the electronic component 50W through electrical communication by the transmission path P3A.

According to some arrangements of the present disclosure, the power modules 80, the optical engines 40, and the electronic components 50 are stacked vertically, and thus the device area in horizontal directions can be reduced. In addition, the cooling device 90 is further vertically stacked on and contacting the electronic components 50, and thus the heat dissipation can be achieved without increasing the device area in horizontal directions.

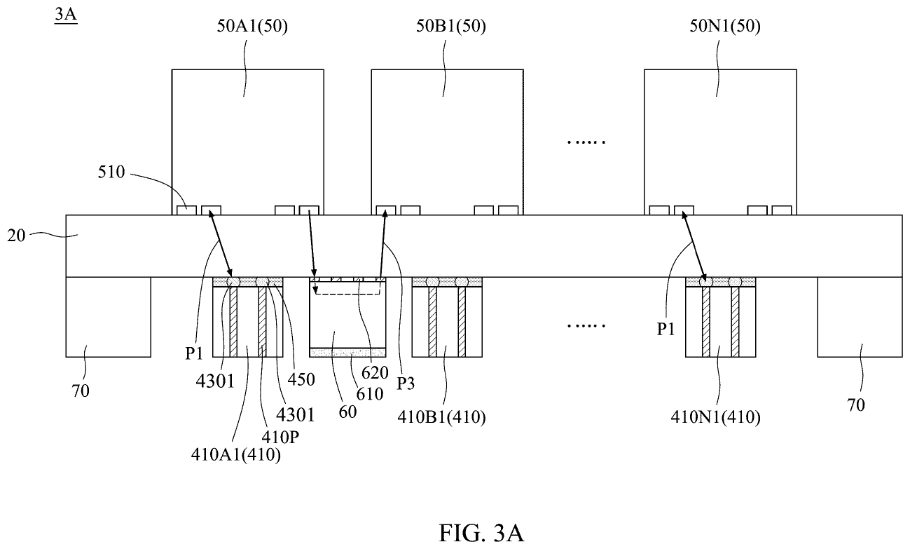

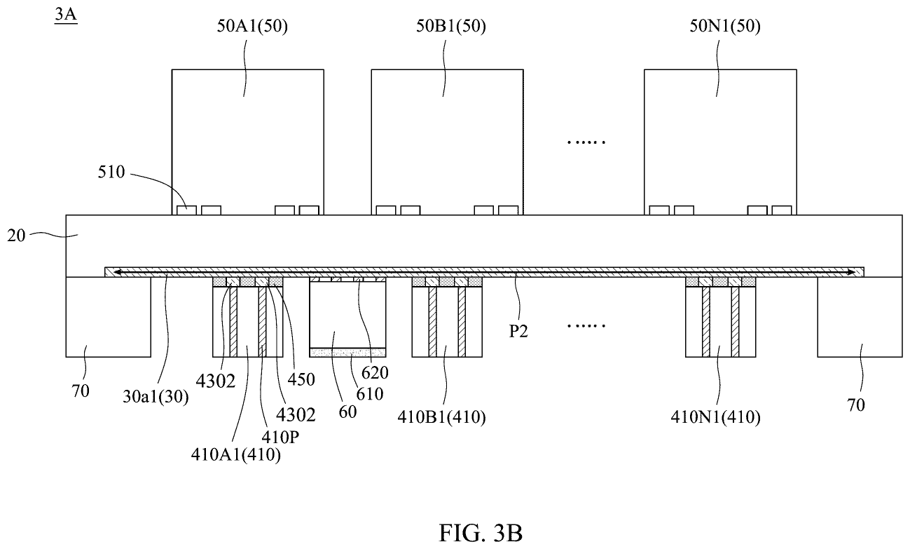

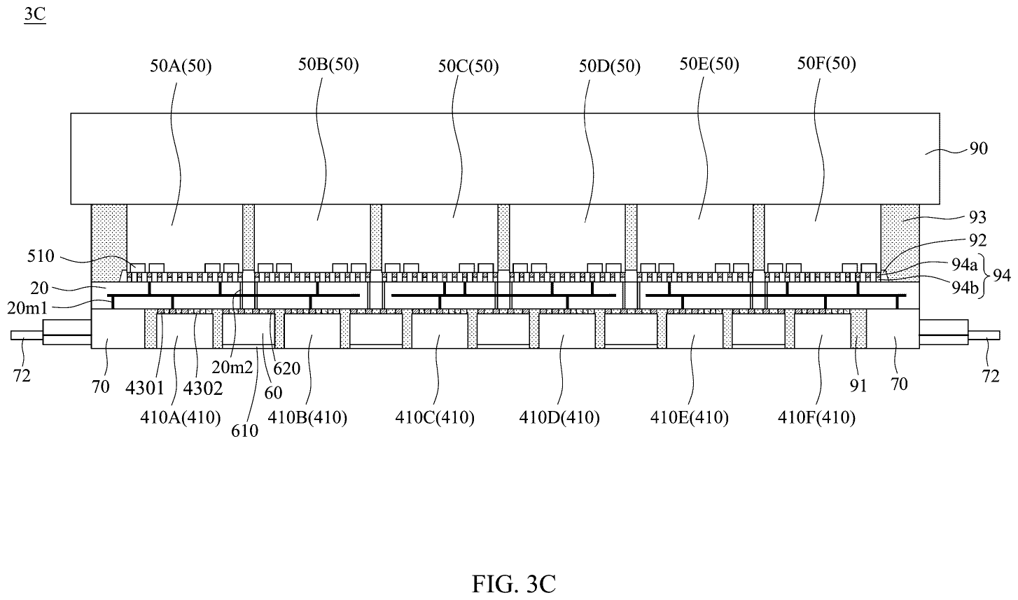

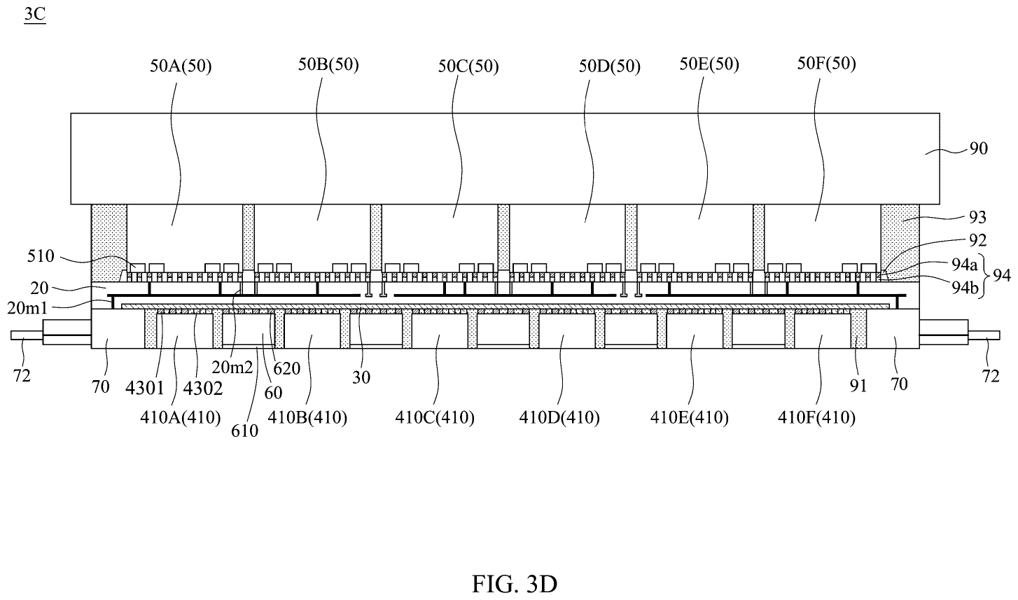

FIG. 3A is a cross-section of an electronic device 3A in accordance with some arrangements of the present disclosure. FIG. 3A is a cross-section of an electronic device 3A in accordance with some arrangements of the present disclosure. In some arrangements, FIG. 3A and FIG. 3B are cross-sections along different cross-sectional lines in FIG. 1B. For example, FIG. 3B may be a cross-section along the line 1A-1A′ in FIG. 1B, and FIG. 3A may be a cross-section along another line substantially parallel to the line 1A-1A′ in FIG. 1B. The electronic device 3A is similar to the electronic device 1 in FIG. 1A and FIG. 1B, and the differences therebetween are described as follows.

In some arrangements, each of the electronic components 50 may include or be integrated with an electronic element (e.g., an EIC that is the same as or similar to the electronic element 420 illustrated in FIG. 1A and FIG. 1B). In some arrangements, the electronic component 50 includes a processing component (e.g., ASIC) and an EIC integrated with the processing component.

In some arrangements, the electronic device 3A includes connection elements 4301 and 4302 connected to the transducers 410. In some arrangements, referring to FIG. 3B, the circuit 30 (or the optical channel) is disposed between the photonic component (e.g., the transducer 410) and the electronic components 50 and optically coupled to the photonic component (e.g., the transducer 410). In some arrangements, the transducers 410 directly connect to the circuit 30. In some arrangements, the transducer 410 is electrically connected to the circuit 20 through the connection element 4301 as illustrated in FIG. 3A, and the transducer 410 is optically coupled to the circuit 30 through the connection element 4302 as illustrated in FIG. 3B. In some arrangements, the connection elements 4301 and 4302 are formed of or include different materials. In some arrangements, the connection element 4301 is or includes an electrically conductive material. In some arrangements, the connection element 4302 is or includes an optical waveguide material. In some arrangements, the electronic component 50 is electrically connected to the transducer 410 through the circuit 20 and the connection element 4301 along the transmission path P1. In some arrangements, the transducer 410 is optically coupled to the circuit 30 through the connection element 4302.

According to some arrangements of the present disclosure, the EIC is integrated in the electronic component 50, and the optical mesh network (e.g., the circuit 30) is disposed between the electronic component 50 and the transducer 410, and thus the interconnection structure (e.g., conductive layers or a wiring structure) that is outside of the electronic component 50 and electrically connecting between the electronic component 50 and the electronic element 420 of the optical engine 40 can be omitted. For example, the conductive layers or the wiring structure in the circuit 20 for electrically connecting between the electronic component 50 and the transducer 410 of the optical engine 40 can be omitted. Therefore, the number of conductive layers within the circuit 20 can be reduced, and thus the thickness of the circuit 20 can be reduced. In addition, according to some arrangements of the present disclosure, with the optical channel (e.g., the circuit 30) is formed on or within the circuit 20, an additional circuit (e.g., the circuit 20B illustrated in FIG. 2A) can be omitted, and thus the length of the power path between the electronic components 50 and power modules disposed under the photonic components (e.g., the transducers 410) can be reduced, which further reduces power consumption.

FIG. 3C is a cross-section of an electronic device 3C in accordance with some arrangements of the present disclosure. FIG. 3D is a cross-section of an electronic device 3C in accordance with some arrangements of the present disclosure. In some arrangements, FIG. 3C and FIG. 3D are cross-sections along different cross-sectional lines of the electronic device 3C. The electronic device 3C is similar to the electronic device 3A in FIGS. 3A-3B, and the differences therebetween are described as follows.

In some arrangements, each of the electronic components 50 may include or be integrated with an electronic element (e.g., an EIC that is the same as or similar to the electronic element 420 illustrated in FIG. 1A and FIG. 1B). In some arrangements, the electronic component 50 includes a processing component (e.g., ASIC) and an EIC integrated with the processing component.

In some arrangements, the electronic device 3C further includes the encapsulants 91 and 93, the underfill 92, and the connection elements 94. The circuit 20 includes conductive structures 20m1 and 20m2. The above elements are similar to those illustrated in FIG. 2A, and the description thereof is omitted hereinafter.

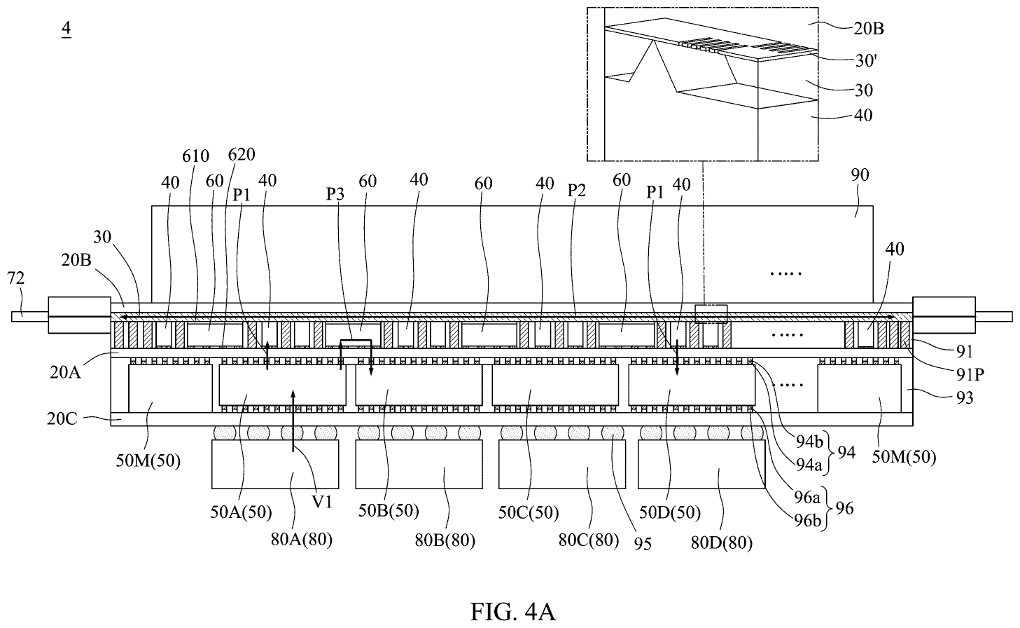

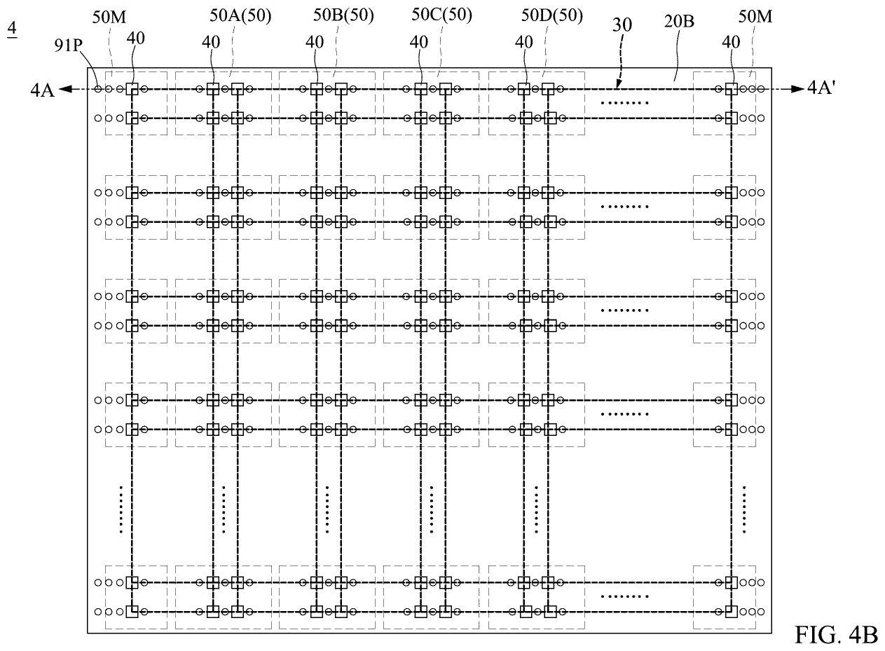

FIG. 4A is a cross-section of an electronic device 4 in accordance with some arrangements of the present disclosure. FIG. 4B is a top view of an electronic device 4 in accordance with some arrangements of the present disclosure. In some arrangements, FIG. 4A shows a cross-section along a line 4A-4A′ in FIG. 4B. The electronic device 4 is similar to the electronic device 2 in FIG. 2A and FIG. 2B, and the differences therebetween are described as follows.

In some arrangements, the circuit structure 10 further includes a circuit 20C between the electronic components 50 and the power modules 80. In some arrangements, the electronic device 4 further includes connection elements 96 connecting the electronic components 50 to the circuit 20C. Each of the connection elements 96 may include portions 96a and 96b. The portion 96a may be a conductive pad or stud, and the portion 96b may be a solder bump.

In some arrangements, at least the circuit structure 10, the optical engines 40, and the bridge component 60 may collectively construct an optoelectronic interposer. In some arrangements, the pillars 91P (or the thermal pipes) are embedded in the optoelectronic interposer and configured to dissipate heat from the electronic components 50 to the cooling device 90.

In some arrangements, the electronic components 50 include active surfaces on opposite sides. In some arrangements, the optical engines 40 and the bridge components 60 are at and connected to a side (e.g., a first side or an upper side) of the electronic components 50. In some arrangements, the power modules 80 are at and connected to an opposite side (e.g., a second side or a lower side) of the electronic components 50. In some arrangements, the power modules 80 are configured to provide power to the electronic components 50 along a power path V1 between the power modules 80 and the electronic components 50. In some arrangements, modulated power may be provided along the power path V1 substantially parallel to a transmission path P1 (or the electrical path) of the electrical transmission. In some arrangements, the transmission path P2 (or the optical path) of the optical transmission is longer than the transmission path P1 (or the electrical path) and the power path V1. According to some arrangements of the present disclosure, with the design of the circuit 30 (or the optical channel), the optical engines 40, and the bridge component 60 on one side of the electronic components 50 and the power modules 80 on an opposite side of the electronic components 50, the power path V1 that does not pass through spaces between the optical engines 40 and/or the bridge component 60 is further reduced. In addition, the structure of the power delivery network within the circuit 20C can be simplified without reserving space for disposing or forming an optical channel. Therefore, the power consumption can be further reduced, and the overall structure as well as the manufacturing process can be simplified.

In some arrangements, a top surface of the optical engine 40 has a tapered profile or an inclined surface contacting the waveguide material of the circuit 30. In some arrangements, a patterned layer 30′ (e.g., a patterned silicon layer) is further disposed between the circuit 20B and the circuit 30.

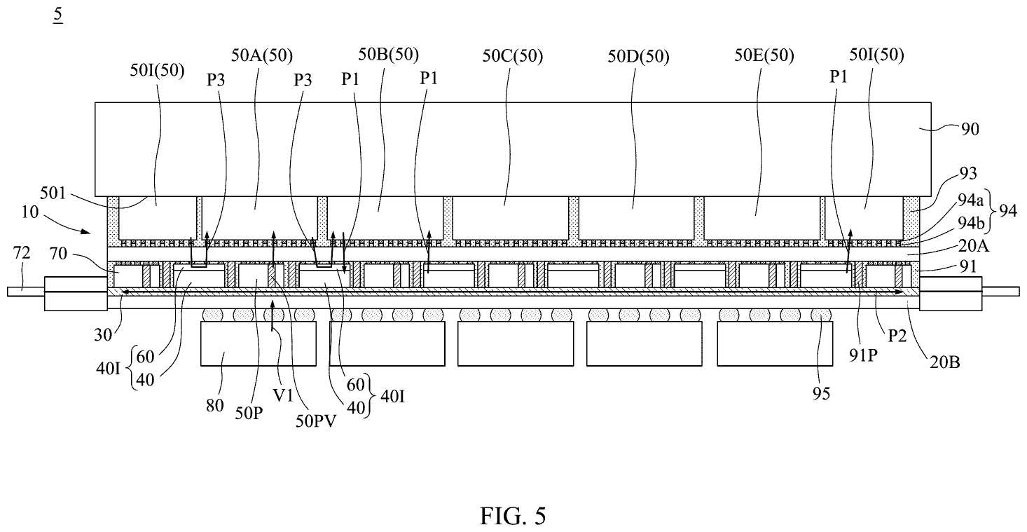

FIG. 5 is a cross-section of an electronic device 5 in accordance with some arrangements of the present disclosure. The electronic device 5 is similar to the electronic device 4 in FIG. 4A and FIG. 4B, and the differences therebetween are described as follows.

In some arrangements, the electronic device 5 includes optoelectronic components 401 and electronic components 50P. In some arrangements, the optoelectronic component 401 is configured to provide a photoelectric conversion at the transmission path P2 and provide the electrical communication between adjacent electronic components 50 (e.g., the electrical communication from the electronic component 50A1 to the electronic component 50B1). In some arrangements, the electronic components 50P are disposed between the optoelectronic components 401. The electronic component 50P may be or include a passive component, e.g., a capacitor, an inductor, or other suitable passive component. In some arrangements, the electronic component 50P is or includes a power regulating element (e.g., a voltage regulating module (VRM)). In some arrangements, the power modules 80 are disposed under the circuit 20B and configured to provide power to the electronic components 50 through the power regulating elements (e.g., the electronic components 50P). In some arrangements, the electronic component 50P may include at least one conductive via 50PV extending between a top surface and a bottom surface of the electronic component 50P, the power path V1 passes the circuit 20B and the power regulating element (e.g., the conductive via 50PV of the electronic components 50P).

In some arrangements, the optoelectronic component 401 includes a transducer (e.g., a transducer of an optical engine 40) and a bridge element (e.g., the bridge component 60) integrated with the transducer. In some arrangements, the optoelectronic component 401 includes an optical engine 40 and a bridge component 60 integrated with the optical engine 40. In some arrangements, the bridge component 60 is configured to provide the electrical communication between the electronic component 50A1 and the electronic component 50B1, and the optical engine 40 (or the transducer) is configured to provide the photoelectric conversion for the optical communication between the electronic component 50A1 and the electronic component 50N1. In some arrangements, the bridge component 60 may be or include a patterned conductive layer or a patterned conductive trace formed on a top surface of the optical engine 40. In some arrangements, the circuit 20B includes an optical channel (e.g., the circuit 30) configured to optically couple to the optoelectronic components 401 and provide an optical communication between the optoelectronic components 401.

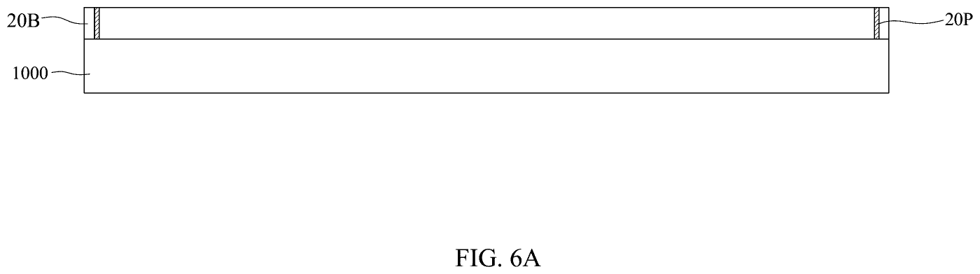

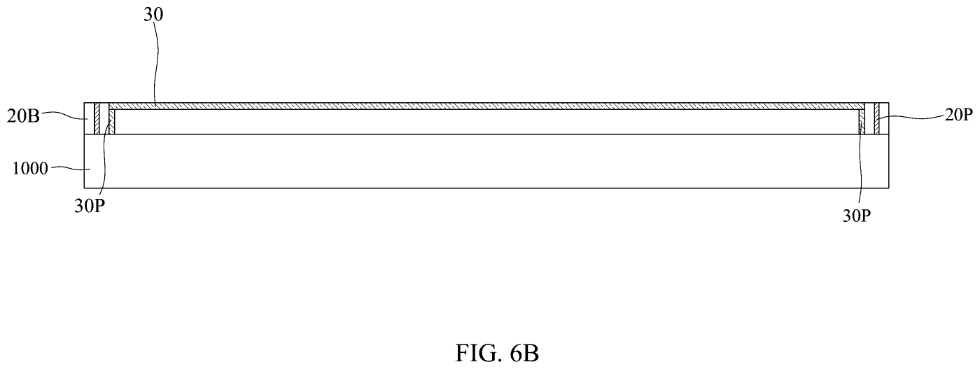

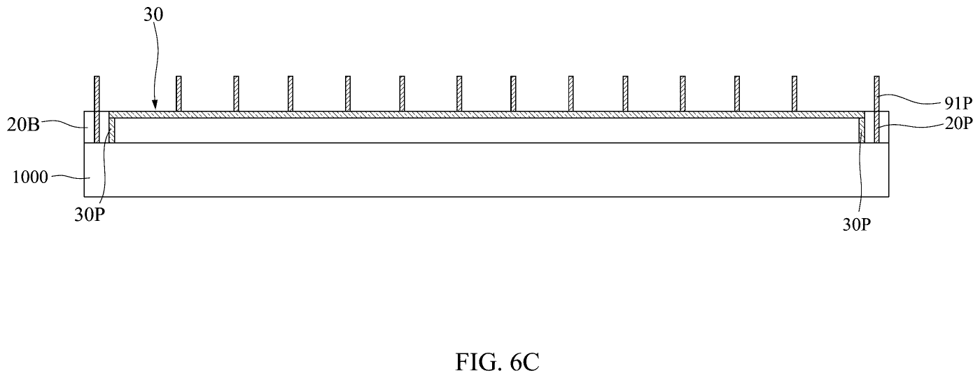

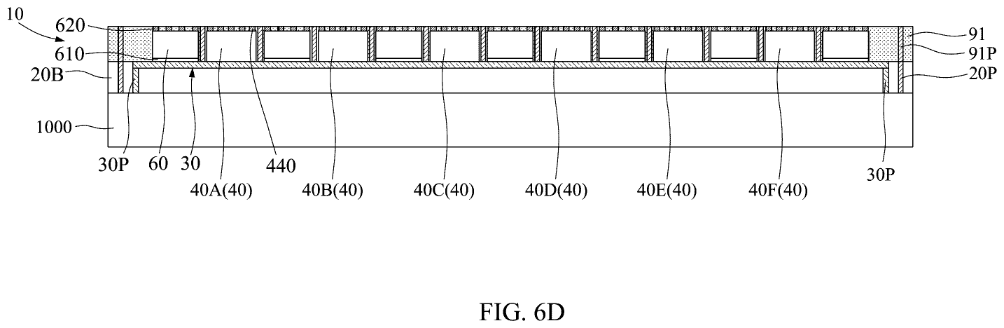

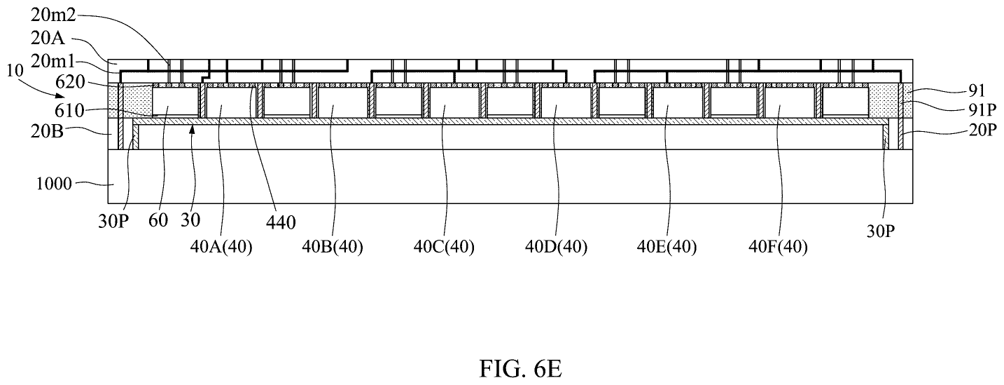

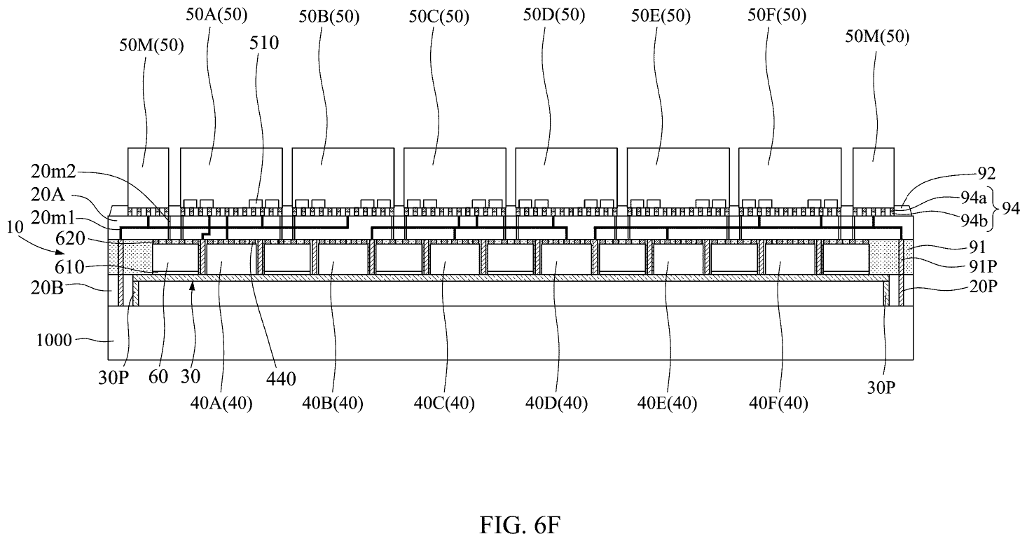

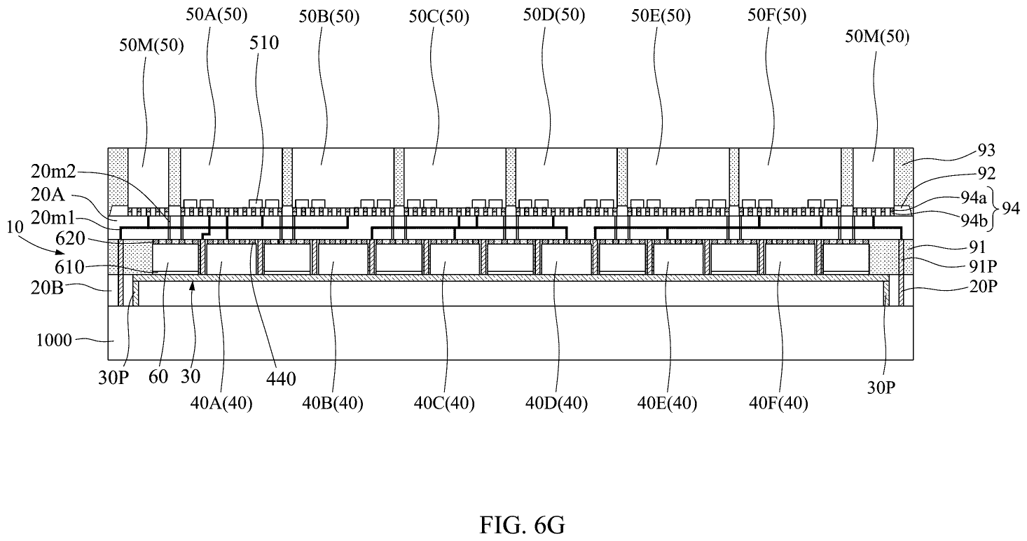

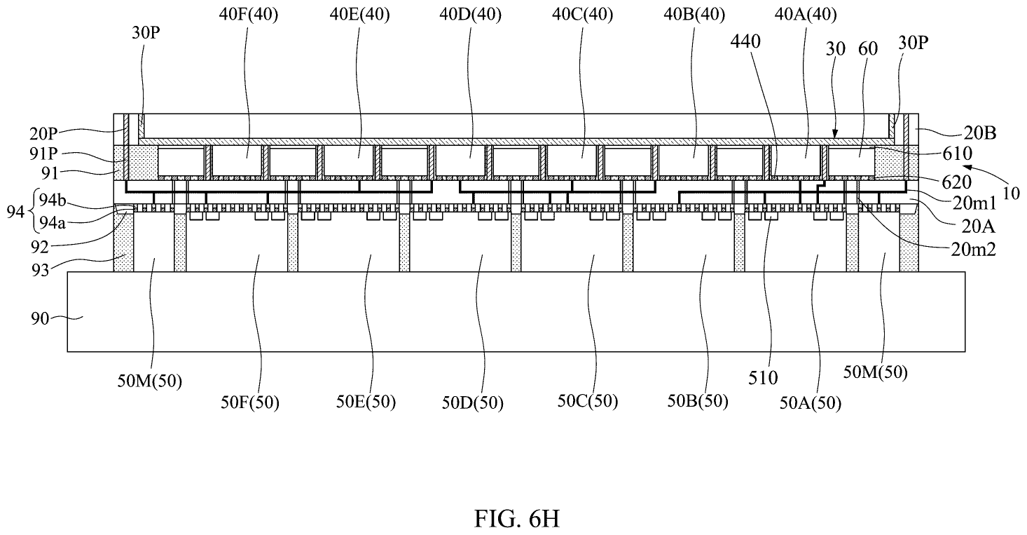

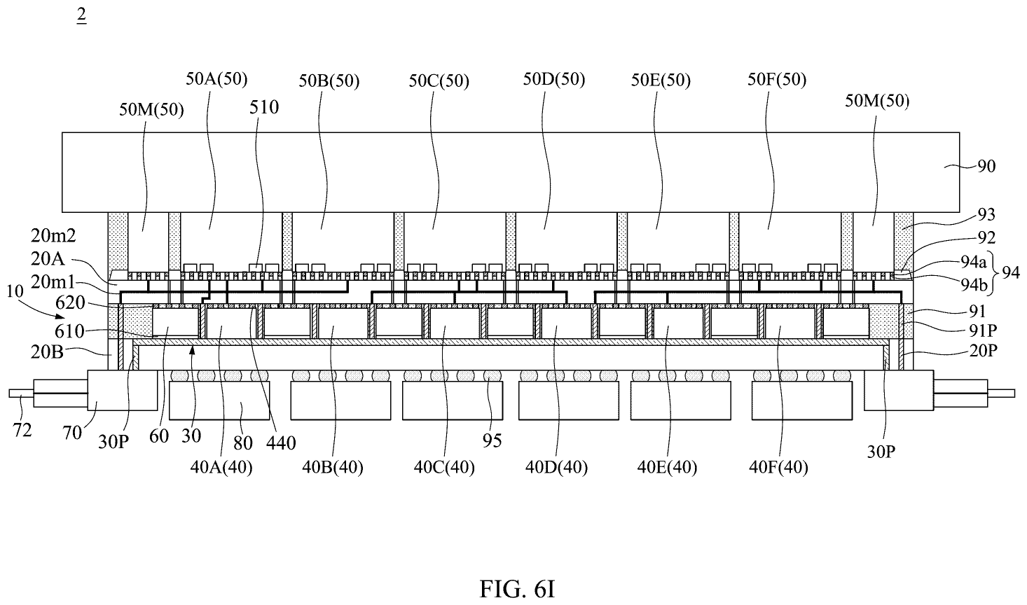

FIG. 6A, FIG. 6B, FIG. 6C, FIG. 6D, FIG. 6E, FIG. 6F, FIG. 6G, FIG. 6H, and FIG. 6I illustrate various stages of an exemplary method for manufacturing an electronic device 2 in accordance with some embodiments of the present disclosure.

Referring to FIG. 6A, a carrier 1000 may be provided, and a circuit 20B may be formed on the carrier 1000. The circuit 20B may include a conductive structure including at least pillars 20P. The pillars 20P may be or include electrically conductive pillars.

Referring to FIG. 6B, a circuit 30 may be formed in the circuit 20B and exposed by a surface of the circuit 20B, and pillars 30P may be further formed in the circuit 20B. The pillars 30P may be or include optical pillars. In some arrangements, the circuit 30 is formed in the dielectric layer of the circuit 20B. The circuit 30 may be or include an optical waveguide, an optical channel, or the like. In some arrangements, the pillars 30P and the circuit 30 may be formed by removing portions of the circuit 20B to form a recessed portion and through holes followed by forming optical waveguide materials in the recessed portion to form the circuit 30 and in the through holes to form the pillars 30P. In some other arrangements, the circuit 30 may be formed on the top surface of the circuit 20B, for example, by deposition.

Referring to FIG. 6C, pillars 91P may be formed on the circuit 20B. The pillars 91P may be or include metal pillars, e.g., Cu pillars.

Referring to FIG. 6D, optical engines 40 and bridge components 60 may be formed on the circuit 20B and between the pillars 91P, and an encapsulant 91 may be formed to encapsulate the optical engines 40 and the bridge components 60. In some arrangements, the optical engines 40 are formed over the optically coupled to the circuit 30. In some arrangements, the bridge components 60 are adhered to the circuit 20B through adhesive layers 610. In some arrangements, connection elements 620 of the bridge components 60 are exposed by the encapsulant 93.

Referring to FIG. 6E, a circuit 20A may be formed on the encapsulant 91 and electrically connected to the optical engines 40 and the bridge components 60.

Referring to FIG. 6F, electronic components 50 may be formed over and connected to the circuit 20A through connection elements 94, and an underfill 92 may be formed to encapsulate the connection elements 94.

Referring to FIG. 6G, an encapsulant 93 may be formed to encapsulate the electronic components 50 and the underfill 92. In some arrangements, an encapsulant material may be formed over the covering the electronic components 50 and the underfill 92, and a grinding operation may be performed on the encapsulant material to expose top surfaces of the electronic components 50 to form the encapsulant 93.

Referring to FIG. 6H, the carrier 1000 may be removed, and the structure illustrated in FIG. 6G may be flipped over and attached to a cooling device 90.

Referring to FIG. 6I, the structures illustrated in FIG. 6H may be flipped over, power modules 80 may be connected to the circuit 20B through connection elements 95, photonic components 70 may be formed to connect to the pillars 20P and 30P, and optical components 72 may be formed to optically coupled to the photonic components 70. In some arrangements, the power modules 80 are attached to the circuit 20B by surface mount technology (SMT). As such, the electronic 2 illustrated in FIGS. 2A and 2B may be formed.

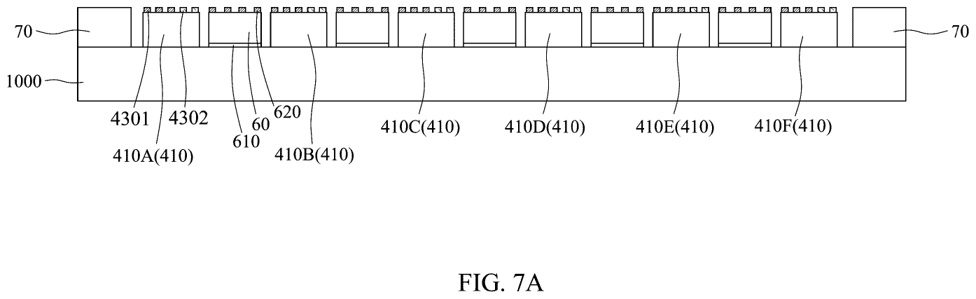

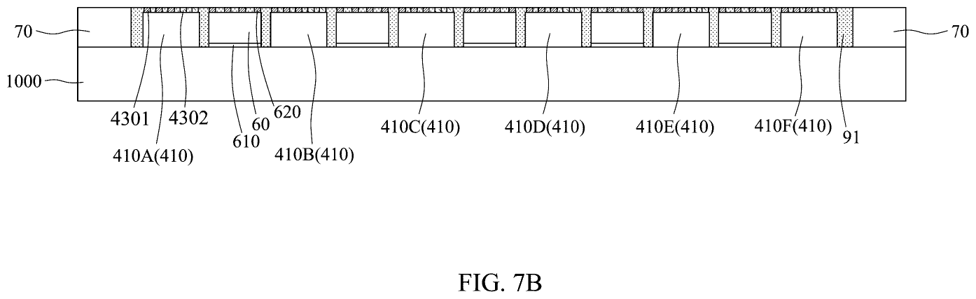

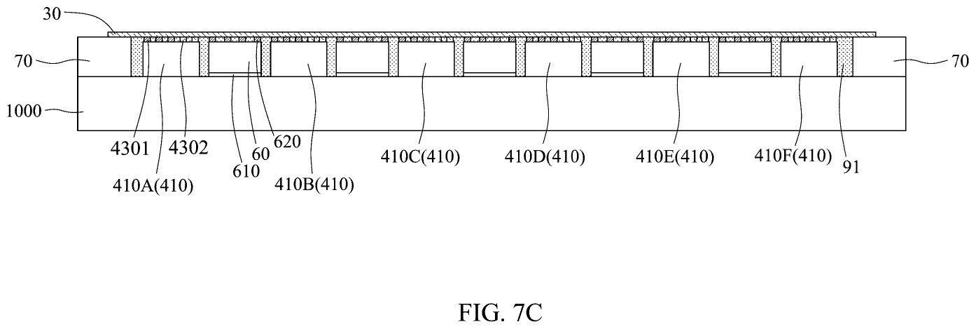

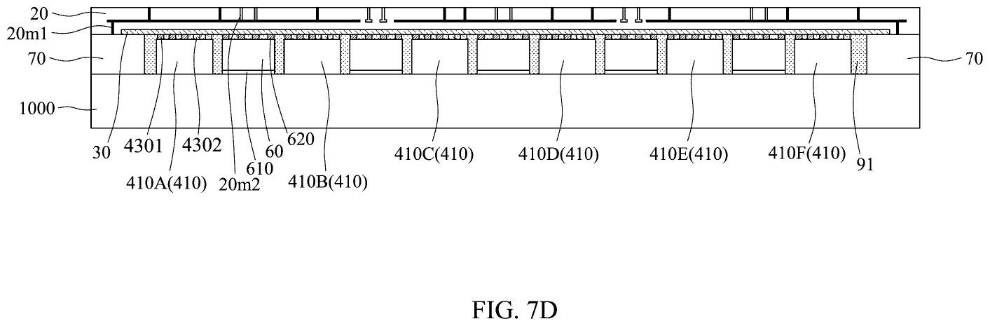

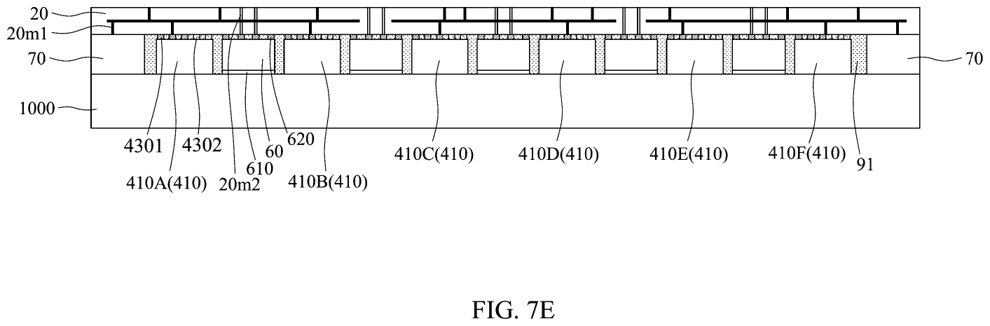

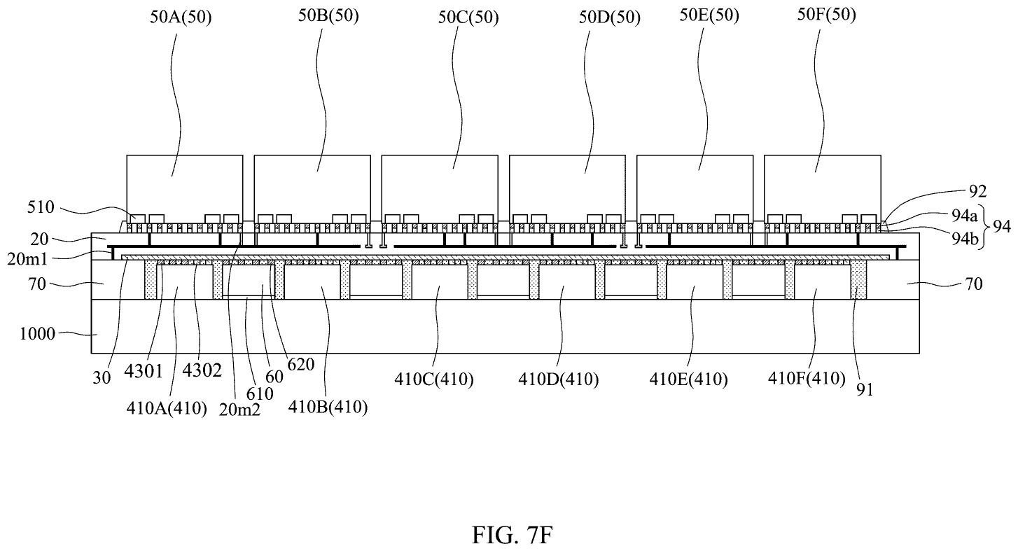

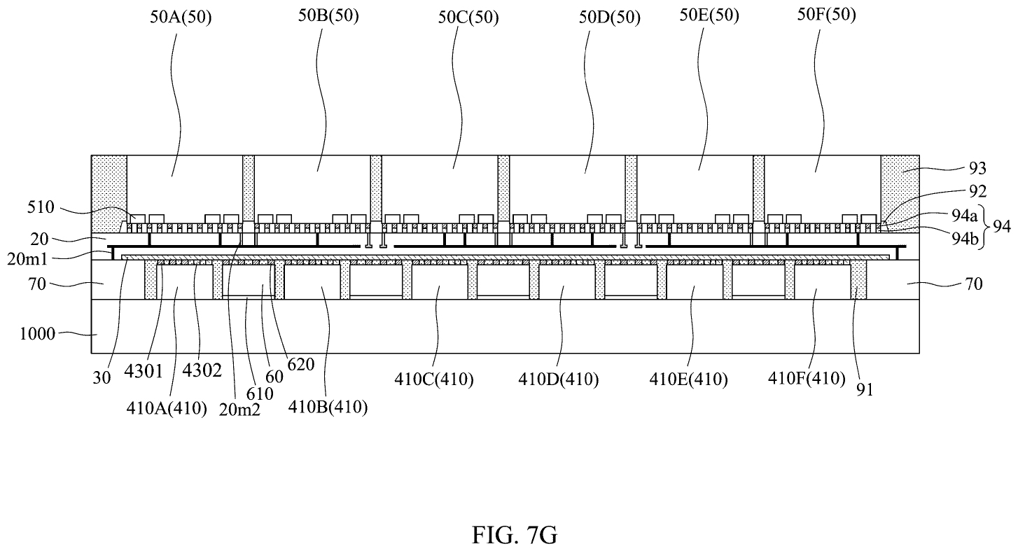

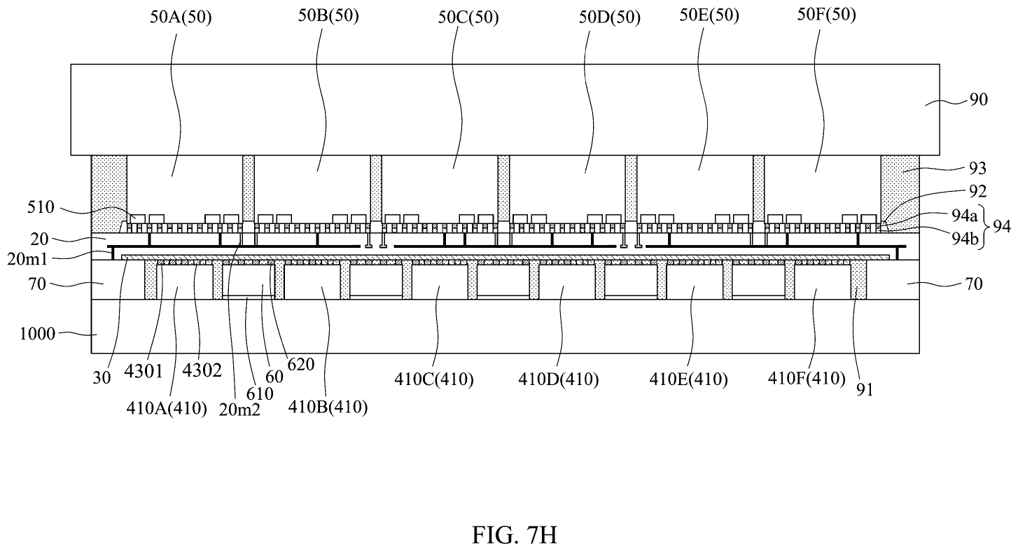

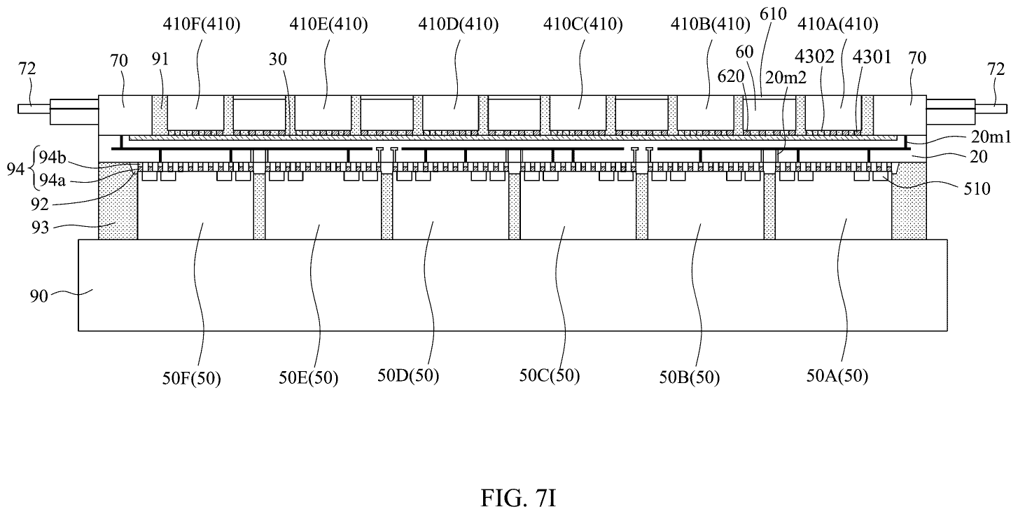

FIG. 7A, FIG. 7B, FIG. 7C, FIG. 7D, FIG. 7E, FIG. 7F, FIG. 7G, FIG. 7H, and FIG. 7I illustrate various stages of an exemplary method for manufacturing an electronic device 3C in accordance with some embodiments of the present disclosure.

Referring to FIG. 7A, a carrier 1000 may be provided, transducers 410, bridge components 60, and photonic components 70 may be disposed on or attached to the carrier 1000. In some arrangements, the transducers 410 and the photonic components 70 are formed or disposed on the carrier 1000. In some arrangements, the bridge components 60 are adhered to the carrier 1000 through adhesive layers 610.

Referring to FIG. 7B, an encapsulant 91 may be formed to encapsulate the transducers 410, the bridge components 60, and the photonic components 70. In some arrangements, an encapsulant material may be formed over the covering the transducers 410, the bridge components 60, and the photonic components 70, and a grinding operation may be performed on the encapsulant material to expose top surfaces of the photonic components 70, connection elements 4301 and 4302 of the transducers 410, and connection elements 620 of the bridge components 60 to form the encapsulant 91.

Referring to FIG. 7C, a circuit 30 may be formed over the encapsulant 91. In some arrangements, the circuit 30 is optically coupled to the transducers 410 and the photonic components 70.

Referring to FIG. 7D and FIG. 7E, which show different cross-sections along different cross-sectional lines, a circuit 20 may be formed over the circuit 30. As shown in FIG. 7D, the conductive structure 20m1 of the circuit 20 may be formed over and spaced apart from the circuit 30. As shown in FIG. 7E, the circuit 20 may be electrically connected to the transducers 410, the bridge components 60, and the photonic components 70 in a different cross-sectional view perspective.

Referring to FIG. 7F, electronic components 50 may be disposed over the circuit 20. In some arrangements, the electronic components 50 may be connected to the circuit 20 through connection elements 94. In some arrangements, an underfill 92 may be formed to encapsulate the connection elements 94.

Referring to FIG. 7G, an encapsulant 93 may be formed to encapsulate the electronic components 50 and the underfill 92. In some arrangements, an encapsulant material may be formed over the covering the electronic components 50 and the underfill 92, and a grinding operation may be performed on the encapsulant material to expose top surfaces of the electronic components 50 to form the encapsulant 93.

Referring to FIG. 7H, a cooling device 90 may be attached to the electronic components 50.

Referring to FIG. 7I, the structure illustrated in FIG. 7G may be flipped over, the carrier 1000 may be removed, and optical components 72 may be attached to the photonic components 70. In some arrangements, the cooling device 90 may serve as a supporting carrier when attaching the optical components 72 to the photonic components 70. As such, the electronic device 3C illustrated in FIGS. 3C-3D may be formed.

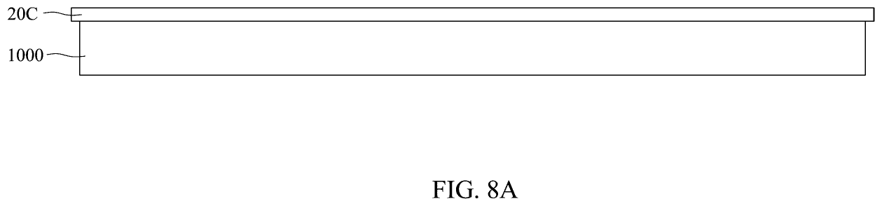

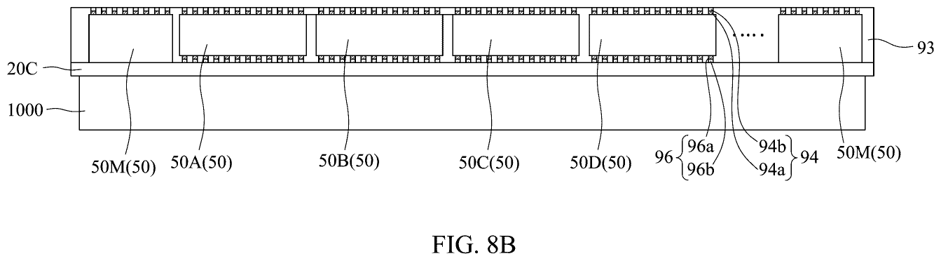

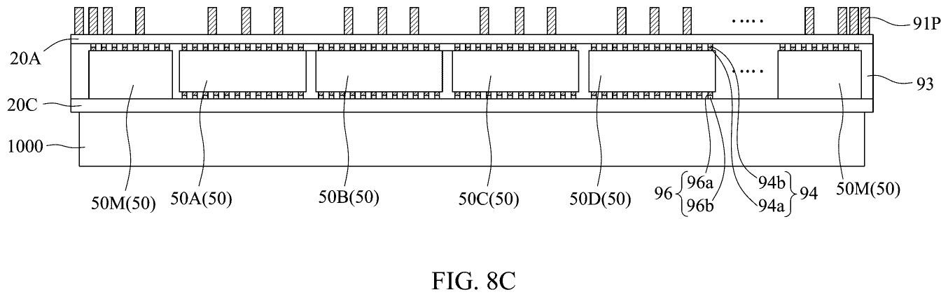

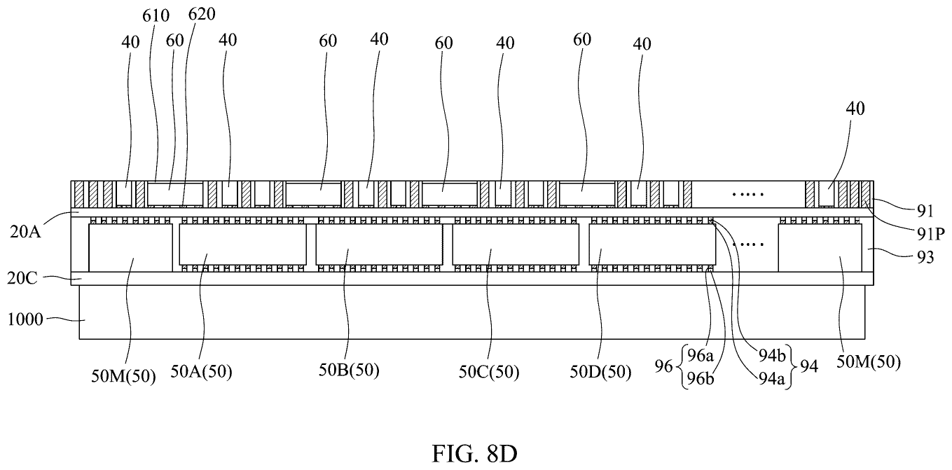

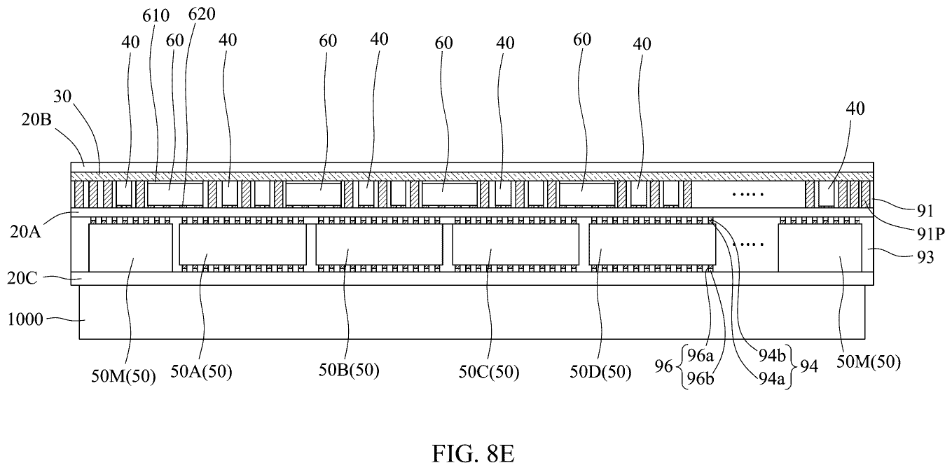

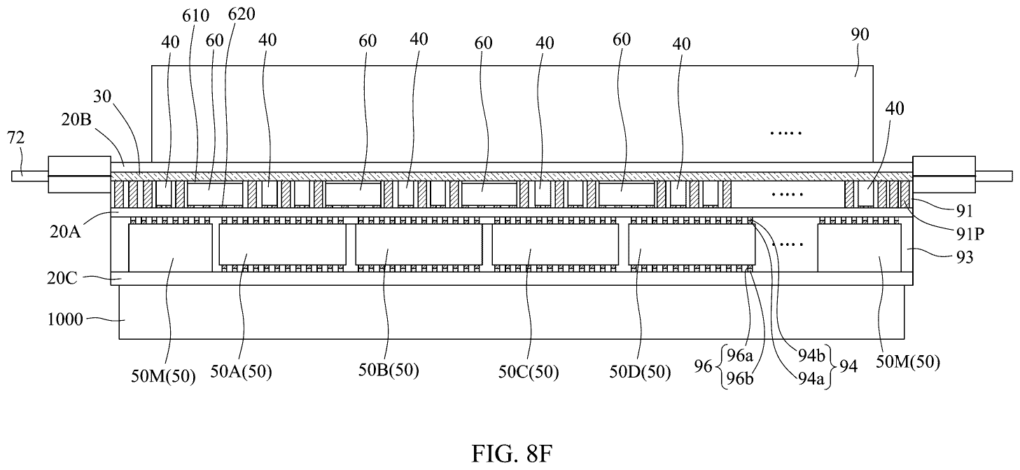

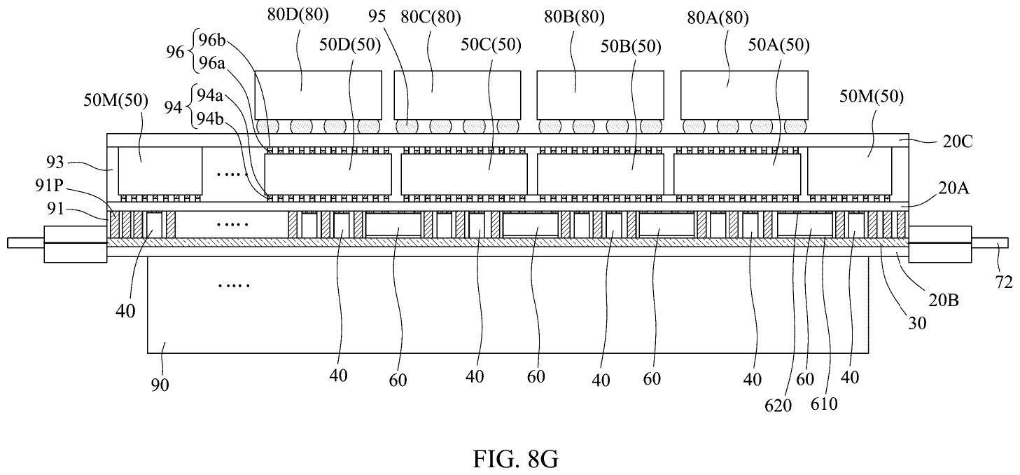

FIG. 8A, FIG. 8B, FIG. 8C, FIG. 8D, FIG. 8E, FIG. 8F, and FIG. 8G illustrate various stages of an exemplary method for manufacturing an electronic device 4 in accordance with some embodiments of the present disclosure.

Referring to FIG. 8A, a carrier 1000 may be provided, and a circuit 20C may be formed on the carrier 1000.

Referring to FIG. 8B, electronic components 50 may be formed over and connected to the circuit 20C through connection elements 96, and an encapsulant 93 may be formed to encapsulate the electronic components 50. In some arrangements, an encapsulant material may be formed over the covering the electronic components 50, and a grinding operation may be performed on the encapsulant material to expose connection elements 94 of the electronic components 50.

Referring to FIG. 8C, a circuit 20A may be formed on the electronic components 50 and the encapsulant 93, and pillars 91P may be formed on the circuit 20A. The pillars 91P may be or include metal pillars, e.g., Cu pillars.

Referring to FIG. 8D, optical engines 40 and bridge components 60 may be formed on the circuit 20A and between the pillars 91P, and an encapsulant 91 may be formed to encapsulate the optical engines 40 and the bridge components 60. In some arrangements, the optical engines 40 are formed over the electrically connected to the circuit 20A. In some arrangements, the bridge components 60 are electrically connected to the circuit 20A through connection elements 620.

Referring to FIG. 8E, a circuit 30 may be formed on the encapsulant 91 and optically coupled to the optical engines 40, and a circuit 20B may be formed on the encapsulant 91. In some arrangements, referring to FIG. 4A, top surfaces of the optical engines 40 may be etched to form tapered profiles or inclined surfaces, the circuit 30 is formed on the top surfaces of the optical engines 40. In some arrangements, referring to FIG. 4A, a patterned layer 30′ may be further formed on the circuit 30 by depositing a material (e.g., a silicon layer) followed by patterning the material to form the patterned layer 30′ on the circuit 30.

Referring to FIG. 8F, optical components 72 may be attached to the circuit 30, and a cooling device 90 may be disposed over the circuit 20B.

Referring to FIG. 8G, the structure illustrated in FIG. 8F may be flipped over, the carrier 1000 may be removed, and power modules 80 may be connected to the circuit 20C through connection elements 95. In some arrangements, the cooling device 90 may serve as a supporting carrier when disposing the power modules 80 over the circuit 20C. As such, the electronic device 4 illustrated in FIGS. 4A and 4B may be formed.

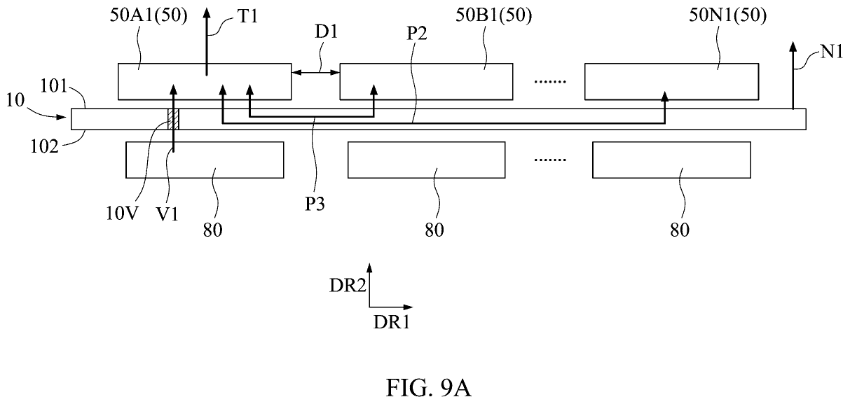

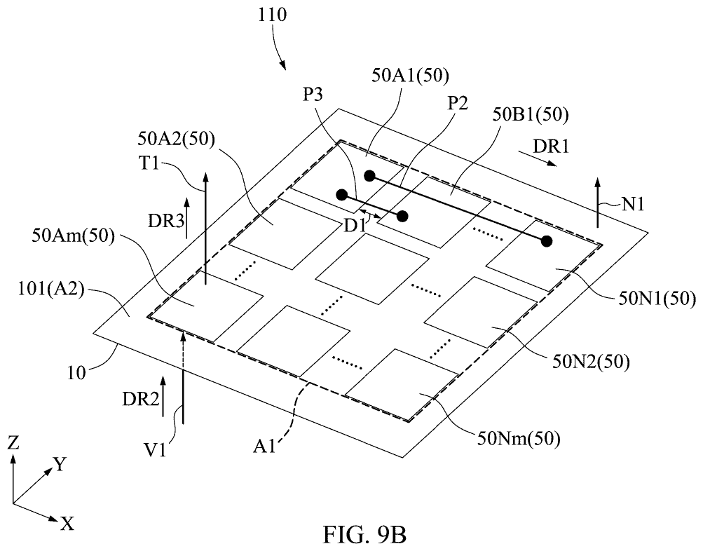

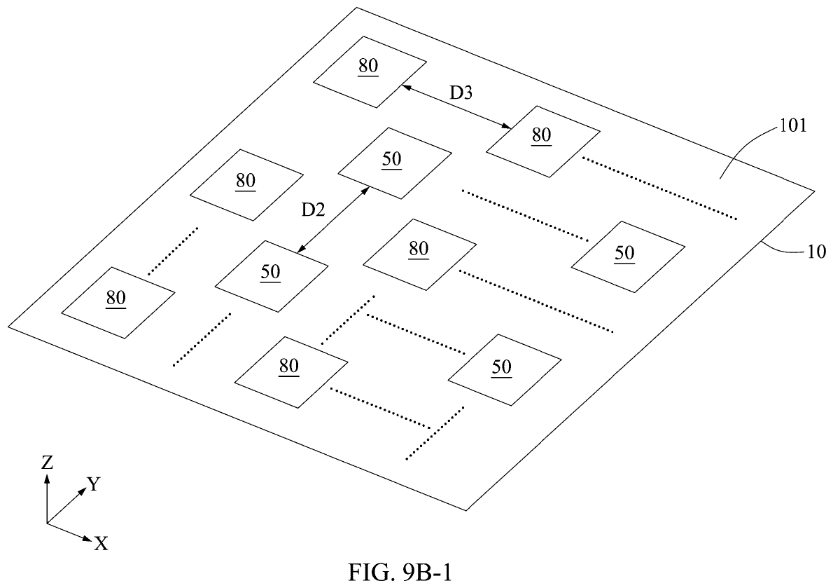

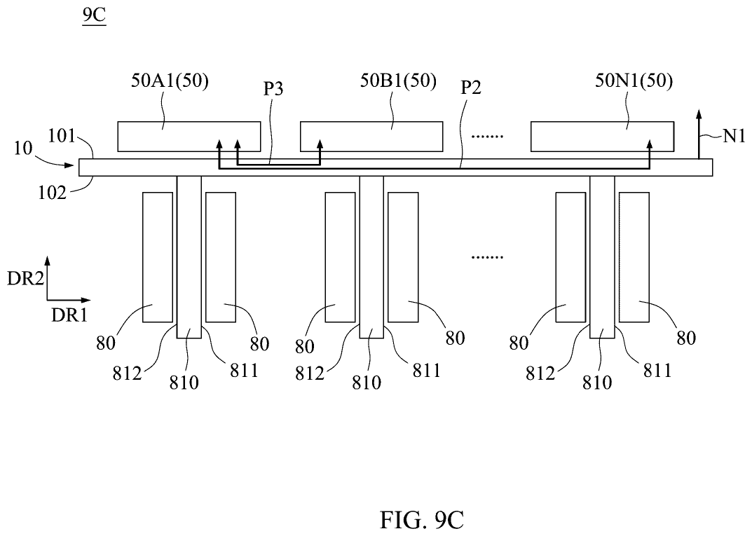

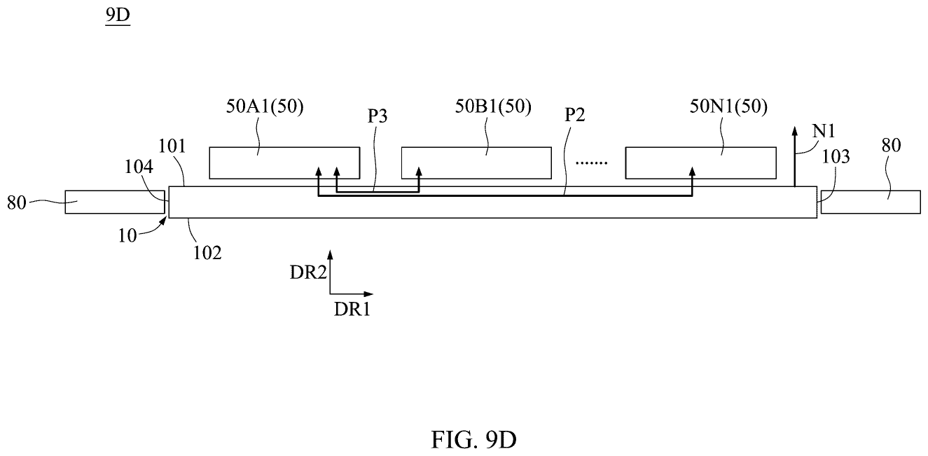

FIG. 9A is a cross-section of an electronic device 9 in accordance with some arrangements of the present disclosure. FIG. 9B is a top view of an electronic device 9 in accordance with some arrangements of the present disclosure. Please be noted that some elements/components are omitted in the electronic device 9 shown in FIG. 9A and FIG. 9B. FIG. 9A and FIG. 9B are intended to show main concepts of the structure of the electronic device 9 rather than the detailed structure thereof. In some arrangements, the electronic device 9 may include some elements/components of the electronic devices 1, 2, 3A, 3C, 4, and/or 5 illustrated aforementioned to possess required functions.

The electronic device 9 may include at least a processing array 110, a circuit 30 (also referred to as an optical channel), and power modules 80 (also referred to as power units).

In some arrangements, the processing array 110 may be constituted by a plurality of processing units (e.g., the electronic components 50A1 to 50Nm) arranged in columns and rows. For example, the processing array 110 may include N columns and m rows of processing units. In some arrangements, the processing array 110 may be constituted by the electronic components 50A1 to 50N1 (or the processing units) in N columns and the electronic components 50A1 to 50Am (or the processing units) in m rows. In some arrangements, as shown in FIG. 1B, the processing array 110 may have or occupy an area A1. In some arrangements, a distance D1 between two adjacent processing units (or two adjacent ones of the electronic components 50A1 to 50Nm) is substantially equal to or less than 100 micrometers (m). In some arrangements, the distance D1 between two adjacent processing units (or two adjacent ones of the electronic components 50A1 to 50Nm) is less than about 90 μm, 80 μm, 70 μm, 60 μm, or 50 μm. In some arrangements, the processing unit (or the electronic components 50A1 to 50Nm) may have a size or an area from about 25 mm×25 mm to about 50 mm×50 mm.

In some arrangements, the electronic device 9 may include a surface 101 supporting the processing array 110. In some arrangements, the electronic components 50A1 to 50Nm are supported by the surface 101. In some arrangements, the surface 101 may have an area A2, and the area A1 of the processing array 110 is greater than about 80% of the area A1 of the surface 101. In some arrangements, the area A1 is greater than about 85% or 90% of the area A1. In some arrangements, the processing array 110 includes 81 processing units constituted by 9 columns and 9 rows, each of the processing units has an area of about 30 mm×30 mm, the distance between adjacent processing units is about 100 m, the surface 101 may have the area A2 of about 300 mm×300 mm, and the ratio of the area A1 with respect to the area A2 is about 81%. In some arrangements, the processing array 110 includes 121 processing units constituted by 11 columns and 11 rows, each of the processing units has an area of about 25 mm×25 mm, the distance between adjacent processing units is about 100 m, the surface 101 may have the area A2 of about 300 mm×300 mm, and the ratio of the area A1 with respect to the area A2 is about 85%.

In some arrangements, the electronic device 9 may further include a surface 102 distinct from the surface 101. The surface 101 may be opposite to the surface 102.

In some arrangements, the circuit 30 (or the optical channel) is configured to transmit a signal (also referred to as “a first signal” or “an optical signal”) between at least two of the processing units (or the electronic components 50A1 to 50Nm) in a direction DR1 that is nonparallel with a normal direction N1 of the surface 101. The direction DR1 may be substantially perpendicular to the normal direction N1 of the surface 101. In some arrangements, the circuit 30 (or the optical channel) is configured to transmit the signal (or the first signal or the optical signal) through a transmission path P2. In some arrangements, the processing units (or the electronic components 50A1 to 50Nm) are configured to receive power in a direction DR2 different from the direction DR1 in which the circuit 30 (or the optical channel) is configured to transmit the signal (or the first signal or the optical signal) between at least two of the processing units. The direction DR2 may be substantially parallel with the normal direction N1 of the surface 101.

In some arrangements, the electronic device 9 may further include an electrical channel configured to transmit a signal (also referred to as “a second signal” or “an electrical signal”) between two adjacent one of the processing units (or the electronic components 50A1 to 50Nm). In some arrangements, the electrical channel is configured to transmit the signal (or the second signal or the electrical signal) through a transmission path P3. In some arrangements, the electrical channel is configured to transmit the signal (or the second signal or the electrical signal) in a direction that is nonparallel with (e.g., perpendicular to) the normal direction N1 of the surface 101. In some arrangements, the transmission path P2 is greater or longer than the transmission path P3.

In some arrangements, the electronic device 9 may further include a circuit structure 10 including the circuit 30 (or the optical channel) and having the surfaces 101 and 102. In some arrangements, the circuit structure 10 further includes the electrical channel configured to transmit the signal (or the second signal or the electrical signal) between two adjacent one of the processing units (or the electronic components 50A1 to 50Nm). In some arrangements, the circuit structure 10 further includes at least a conductive via 10V extending between the surface 101 and the surface 102. The circuit structure 10 may be or include an extremely large scale panel (ELSP), e.g., a panel with a size of 300 mm×300 mm, 600 mm×600 mm, or greater.

In some arrangements, the power modules 80 (or the power units) are configured to transmit or provide power to the processing units. In some arrangements, the power modules 80 (or the power units) are configured to transmit or provide power to the corresponding processing units. For example, each of the power modules 80 may be configured to transmit power to each of the corresponding electronic components 50A1 to 50Nm. In some arrangements, the power units and the processing units are located at different surfaces. In some arrangements, the processing units are supported by the surface 101, and the power units are supported by the surface 102. In some arrangements, the surfaces 101 and 102 are configured to be passed by the power (e.g., one or more power signals from one or more power units). In some arrangements, the power units and the processing units are disposed at opposite sides of the circuit 30 (or the optical channel).

In some arrangements, the electronic device 9 may further include a power path V1 (also referred to as “a power channel”) configured to deliver power through the surface 101 to at least one of the processing units (or the electronic components 50A1 to 50Nm) in a direction (e.g., the direction DR2) different from the direction DR1. In some arrangements, the direction DR2 is substantially in parallel with the normal direction N1 of the surface 101. The power path V1 may be or include an electrical channel (e.g., the conductive via 10V).

In some arrangements, the electronic device 9 may further include a thermal channel T1 configured to transfer heat outwardly from at least one of the processing units (or the electronic components 50A1 to 50Nm) in a direction DR3 without intersecting with the surface 101. In some arrangements, the thermal channel T1 extends outwardly from least one of the processing units (or the electronic components 50A1 to 50Nm) without intersecting with the surface 101. The direction DR3 may be substantially parallel to the direction DR2 and/or the normal direction N1. The direction DR3 may be perpendicular to the direction DR1.

Currently, referring FIG. 9B-1, which is a top view of an electronic device in accordance with some arrangements of the present disclosure, processing units (electronic components 50) and power units (power modules 80) may be disposed on or supported by the same surface (e.g., the surface 101), and thus the number of the processing units arranged on the surface (e.g., the number of the processing units per unit area) is limited due to that a portion of surface is left for arranging the power units. As such, the quantity of computations may be limited, which may reduce the computational capability of the processing units. In contrast, according to some arrangements of the present disclosure, referring to at least FIG. 9A and FIG. 9B, the processing array 110 is supported by the surface 101, and the area of the processing array is greater than 80% of the surface of the surface 101. Therefore, a relatively compact arrangement of the processing units is achieved, thus the quantity of computations can be maximized, which can increase the computational capability of the processing units of the electronic device 1.

Moreover, according to some arrangements of the present disclosure, the processing units and the power units are supported by two distinct surfaces, such that not only the processing units can be arranged in a relatively compact manner, but the power units can also be arranged in a relatively compact manner. Therefore, the performance of the electronic device 1 can be further enhanced.

Furthermore, referring to FIG. 9B-1, when processing units (e.g., the electronic components 50) and power units (e.g., the power modules 80) are disposed on or supported by the same surface (e.g., the surface 101), and horizontal distances D2 and D3 between these units may be up to millimeter (mm) scale or even centimeter (cm) scale in order to reduce crosstalk also due to the processing window limitations. As such, power provided from the power unit to the processing unit has to be transmitted through a relatively long distance (i.e., the horizontal distance at the mm scale or the cm scale), which results in a relatively high power loss and/or power consumption. In contrast, according to some arrangements of the present disclosure, referring to at least FIG. 9A and FIG. 9B, the processing units and the power units are supported by two opposite surfaces, such that each pair of the processing unit and the power unit are separated from each other by a vertical distance defined by a thickness of a substantial layer (e.g., the circuit structure 10). The thickness of the circuit structure 10 can be relatively small, e.g., to m scale, such that the distance between the corresponding processing unit and power unit can be reduced to m scale. With such a relatively small distance between the processing unit and the power unit that are on opposite surfaces of the circuit structure 10, the power path can be reduced significantly, and thus the power loss and power consumption can be reduced significantly as well.

In addition, according to some arrangements of the present disclosure, the thermal path T1 is configured to transfer heat outwardly from the processing units without intersecting with the surface 101 for supporting the processing units. Therefore, the heat dissipation passes the thermal path T1 that directs outwardly and upwardly without going downwardly and transmitting through the surface 101, the thermal path T1 is relatively short, and thus heat dissipation performance can be improved.

FIG. 9C is a cross-section of an electronic device 9C in accordance with some arrangements of the present disclosure. The electronic device 9C is similar to the electronic device 9 in FIG. 9A and FIG. 9B, and the differences therebetween are described as follows.

In some arrangements, the electronic device 9C further includes a carrier layer 810 connected to the circuit structure 10 and having the surfaces 811 and 812. In some arrangements, the power modules 80 (or the power units) are disposed on or supported by the surfaces 811 and 812. In some arrangements, the surface 101 for supporting the processing units and the surfaces 811 and 812 for supporting the power units extend in substantially perpendicular directions (e.g., the directions DR1 and DR2).

In some arrangements, the carrier layer 810 includes electrical channels configured to provide power or power signals from the power modules 80 on the surfaces 811 and 812 to the corresponding electronic component 50 (or the processing unit) through the surface 101. In some arrangements, each of the processing units (e.g., electronic components 50A, 50B, and 50C) is configured to receive power from the plurality of power modules 80 connected to each of the carrier layer 810 that connects to the surface 102.

In some arrangements, an arrangement density of the processing units is different from an arrangement density of the power units. The arrangement density may be referred to as a number density or a surface density (or an area density). In some arrangements, a number of the processing units per unit area is different from a number of the power units per unit area. For example, an area of the surface 101 is substantially the same as an area of the surface 102, and a number of the processing units (i.e., three electronic components 50A, 50B, and 50C) over the surface 101 is less than a number of the power units (i.e., six power modules 80) over the surface 102. In some arrangements, a ratio of a total area of the processing units to an area of the surface 101 is different from a ratio of a total area of the power units to an area of the surface 102. For example, a ratio of a total area of the electronic components 50A, 50B, and 50C protected on the surface 101 to an area of the surface 101 is greater than a ratio of a total area of the power modules 80 projected on the surface 102 to an area of the surface 102.

According to some arrangements of the present disclosure, despite that power provided from the power modules 80 may be transmitted through the carrier layer 810 before reaching the surface 101, with the arrangements illustrated in FIG. 9C, one processing unit can receive power from two or more power modules 80 without increasing the area over the surface 102 occupied by the power modules 80. Therefore, the area in x-y plane (or over the surface 102) can be reduced, and a relatively high power can be provided to the processing unit.

FIG. 9D is a cross-section of an electronic device 9D in accordance with some arrangements of the present disclosure. The electronic device 9D is similar to the electronic device 9 in FIG. 9A and FIG. 9B, and the differences therebetween are described as follows.

In some arrangements, the circuit structure 10 further has lateral surfaces 103 and 104 extending between the surface 101 and the surface 102. In some arrangements, the power modules 80 (or the power units) are disposed on and connected to the lateral surfaces 103 and 104. In some arrangements, the circuit structure 10 includes electrical channels configured to provide power or power signals from the power modules 80 on the surfaces 103 and 104 to the corresponding electronic component 50 (or the processing unit) through the surface 101.

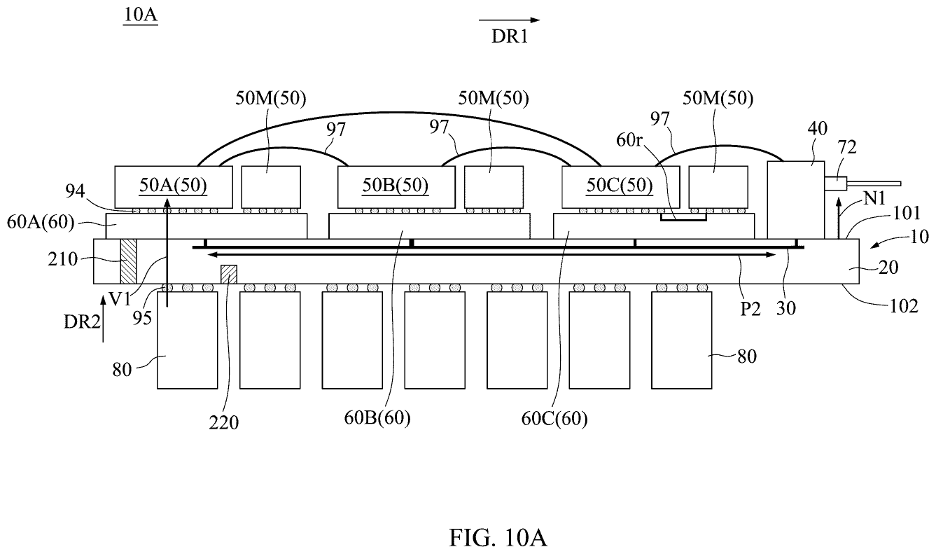

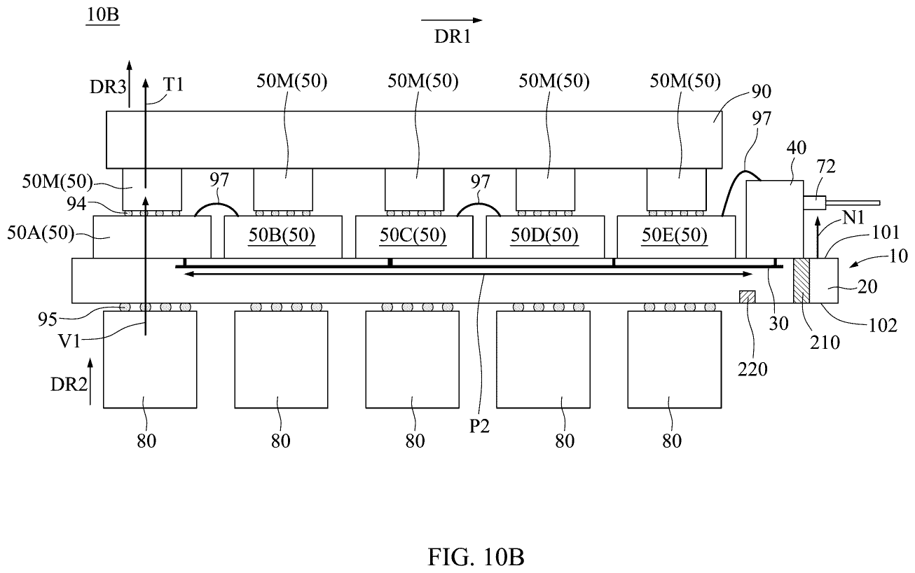

FIG. 10A is a cross-section of an electronic device 10A in accordance with some arrangements of the present disclosure. The electronic device 10A is similar to the electronic device 1 in FIG. 1A and FIG. 1B or the electronic device 9 in FIG. 9A and FIG. 9B, and the differences therebetween are described as follows.

In some arrangements, the electronic device 10A includes a circuit structure 10 including the circuits 20 and 30, optical engines 40, electronic components 50A, 50B, 50C and 50M, bridge components 60, an optical component 72, power modules 80, connection elements 94 and 95, and optical connectors 97.

In some arrangements, the circuit structure 10 includes the circuit 20 (also referred to the electrical channel) and the circuit 30 (also referred to as the optical channel). In some arrangements, the circuit structure 10 further includes embedded devices 210 and 220 electrically connected to the circuit 20. The devices 210 and 220 may independently include an active component or a passive component. The active component may be or include an active bridge element configured for signal communication between two or more of the electronic components 50A, 50B, and 50C. The passive component may be or include an integrated passive device (IPD), e.g., a thin film inductor, a capacitor, or the like. In some arrangements, the circuit structure 10 further includes optical engines (not shown in FIG. 10A) each configured to convert an electrical signal from a processing unit to an optical signal to be transmitted through the optical channel (e.g., the circuit 30).

In some arrangements, the electronic components 50A, 50B, and 50C may be or include processing units (e.g., an ASIC, an FPGA, a GPU, or the like), and the electronic components 50M may be or include memory units (e.g., HBM). In some arrangements, each of the memory units is disposed adjacent to a respective processing unit. Please be noted that the electronic device 10A illustrated in FIG. 10A includes three processing units (i.e., the electronic components 50A, 50B, and 50C) and three memory units (i.e., the electronic components 50M) are for purposes of illustration only, the number of the processing units and the number of the memory units may vary according to actual applications, and the present disclosure is not limited thereto. For example, the electronic device 10A may include a processing array as illustrated in FIG. 9A and FIG. 9B.

In some arrangements, the bridge components 60 (also referred to as bridge elements) are disposed over the surface 101. In some arrangements, each of the bridge component 60 is configured to electrically connect one of the memory units to one of the processing units. In some arrangements, the electronic components 50A, 50B, and 50C and the electronic components 50M are electrically connected to the bridge components 60 through the connection elements 94. In some arrangements, the bridge components 60 include bridge components 60A, 60B, and 60C. In some arrangements, the bridge component 60A is configured to provide electrical communication between the electronic component 50A (or the processing unit) and the adjacent electronic component 50M (or the memory unit). In some arrangements, the bridge component 60B is configured to provide electrical communication between the electronic component 50B (or the processing unit) and the adjacent electronic component 50M (or the memory unit). In some arrangements, the bridge component 60C is configured to provide electrical communication between the electronic component 50C (or the processing unit) and the adjacent electronic component 50M (or the memory unit). In some arrangements, the bridge components 60A and 60B may be or include bridge dies, and the bridge component 60C may be or include a multi-layered interconnection structure including at least a RDL 60r electrically connects the electronic component 50C and the adjacent electronic component 50M (or the memory unit).

In some arrangements, the power modules 80 are electrically connected to the circuit structure 10 through the connection elements 95. In some arrangements, the power path V1 (or the power channel) passes through the connection elements 94 and 95 to provide power to the processing units.

In some arrangements, the optical component 72 may be referred to as an additional optical channel configured to transmit an additional signal (e.g., an additional optical signal) outwardly from the processing array or the processing units (or the electronic components 50A to 50C).

In some arrangements, the optical connectors 97 may be referred to as optical waveguides or photonic wires. In some arrangements, the optical connectors 97 are configured to provide optical communication between the processing units (i.e., the electronic components 50A, 50B, and 50C). In some arrangements, the processing units may include integrated optical engines configured to provide a photoelectric conversion, and the optical connectors 97 are configured to transmit optical signals between the processing units. In some arrangements, the optical connector 97 is further configured to optically communicate at least one of the processing units (e.g., the electronic component 50C) and the optical engine 40, which is optically coupled to the optical component 72.

In some arrangements, an arrangement density of the processing units is different from an arrangement density of the power units. In some arrangements, a number of the processing units per unit area is different from a number of the power units per unit area. For example, an area of the surface 101 is substantially the same as an area of the surface 102, and a number of the processing units (i.e., three electronic components 50A, 50B, and 50C) over the surface 101 is less than a number of the power units (i.e., seven power modules 80) over the surface 102. In some arrangements, a ratio of a total area of the processing units to an area of the surface 101 is different from a ratio of a total area of the power units to an area of the surface 102. For example, a ratio of a total area of the electronic components 50A, 50B, and 50C protected on the surface 101 to an area of the surface 101 is different from a ratio of a total area of the power modules 80 projected on the surface 102 to an area of the surface 102.

According to some arrangements of the present disclosure, with the arrangement of the bridge components 60 and the optical connectors 97, processing units with I/O pins can be arranged in the electronic device 10A, such that various interconnection structures can be used for electrical communication and the optical communication between the processing units. Therefore, the design flexibility can be increased.

FIG. 10B is a cross-section of an electronic device 10B in accordance with some arrangements of the present disclosure. The electronic device 10B is similar to the electronic device 1 in FIG. 1A and FIG. 1B, the electronic device 9 in FIG. 9A and FIG. 9B, or the electronic device 10A in FIG. 10A, and the differences therebetween are described as follows.

In some arrangements, the electronic device 10A further includes a cooling device 90 over the processing units and the memory units. In some arrangements, the cooling device 90 contacts the memory units (e.g., the electronic components 50M).

In some arrangements, each of the memory units is disposed over and connected to a respective processing unit. In some arrangements, each of the electronic components 50A, 50B, 50C, 50D, and 50E (or the processing units) is disposed under and electrically connected to a respective one of the electronic components 50M (or the memory units).

In some arrangements, the power path V1 (or the power channel) is configured to deliver power to at least one of the memory units through at least one of the processing units. In some arrangements, the thermal channel T1 is configured to transfer heat outwardly from at least one of the processing units passing at least one of the memory units and the cooling device 90.

In some arrangements, an arrangement density of the processing units is different from an arrangement density of the power units. In some arrangements, a ratio of a total area of the processing units to an area of the surface 101 is different from a ratio of a total area of the power units to an area of the surface 102. For example, a ratio of a total area of the electronic components 50A, 50B, 50C, 50D, and 50E protected on the surface 101 to an area of the surface 101 is greater than a ratio of a total area of the power modules 80 projected on the surface 102 to an area of the surface 102. In some other arrangements, a size of the power module 80 (or an area of the power module 80 projected on the surface 102) is greater than a size of the processing unit (or an area of the processing unit projected on the surface 101), and a ratio of a total area of the electronic components 50A, 50B, 50C, 50D, and 50E protected on the surface 101 to an area of the surface 101 is less than a ratio of a total area of the power modules 80 projected on the surface 102 to an area of the surface 102.

According to some arrangements of the present disclosure, each of the memory units is disposed over and electrically connected to a corresponding processing unit. The vertical distance between the memory unit and the processing unit can be reduced to m scale, such that the transmission loss between the processing unit and the memory unit can be reduced, and the transmission speed can be increased.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 900 that is less than or equal to ±10°, such as less than or equal to ±5°, less than or equal to ±4°, less than or equal to ±3°, less than or equal to ±2°, less than or equal to ±1, less than or equal to ±0.5°, less than or equal to ±0.1, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a plurality of processing units constituting a processing array having a first area;
a surface supporting the processing array and having a second area, wherein the first area is greater than 80 percent of the second area; and
an optical channel configured to transmit a first signal between at least two of the plurality of processing units in a first direction that is nonparallel with a normal direction of the surface.

2. The electronic device of claim 1, further comprising an electrical channel configured to deliver power through the surface to one of the plurality of processing units in a second direction substantially in parallel with the normal direction of the surface.

3. The electronic device of claim 1, further comprising a thermal channel configured to transfer heat outwardly from one of the plurality of processing units in a second direction without intersecting with the surface.

4. The electronic device of claim 1, further comprising an additional optical channel configured to transmit an additional signal outwardly from the processing array.

5. The electronic device of claim 1, wherein a distance of two adjacent processing units is less than 100 micrometers.

6. The electronic device of claim 5, further comprising a power channel configured to transmit power to the plurality of processing units in a second direction different from the first direction.

7. The electronic device of claim 6, further comprising a plurality of power units configured to transmit the power to the corresponding processing units, wherein the power units and the plurality of processing units are located at different surfaces.

8. The electronic device of claim 5, further comprising an electrical channel configured to transmit a second signal, wherein a path for transmitting the first signal is greater than a path for transmitting the second signal.

9. An electronic device, comprising:
a plurality of processing units supported by a first surface;
a plurality of power units supported by a second surface distinct from the first surface and configured to provide power to the processing units; and
an optical channel configured to transmit a first signal between at least two of the plurality of processing units.

10. The electronic device of claim 9, wherein the first surface and the second surface are configured to be passed by a plurality of power.

11. The electronic device of claim 9, further comprising a circuit structure comprising the optical channel and defining the first surface and the second surface.

12. The electronic device of claim 11, wherein the circuit structure further comprises an electrical channel configured to transmit a second signal between two adjacent ones of the plurality of processing units.

13. The electronic device of claim 9, further comprising:
a circuit structure comprising the optical channel and defining the first surface; and
a carrier layer connected to the circuit structure and defining the second surface, wherein the first surface and the second surface extend in substantially perpendicular directions.

14. The electronic device of claim 9, wherein the plurality of processing units are configured to receive power in a first direction, the optical channel is configured to transmit the first signal between the at least two of the plurality of processing units in a second direction, and the first direction is different from the second direction.

15. An electronic device, comprising:
a plurality of processing units;
a plurality of power units configured to provide power to the corresponding processing units; and
an optical channel configured to transmit a first signal between at least two of the plurality of processing units,
wherein an arrangement density of the plurality of processing units is different from an arrangement density of the plurality of power units.

16. The electronic device of claim 15, wherein the processing units and the power units are disposed at opposite sides of the optical channel.

17. The electronic device of claim 16, further comprising:
a plurality of memory units each disposed adjacent to a respective one of the processing units; and
a plurality of bridge elements each configured to electrically connect one of the memory units to one of the processing units.

18. The electronic device of claim 16, further comprising a plurality of memory units each disposed over and connected to a respective one of the processing units.

19. The electronic device of claim 18, further comprising an electrical channel configured to deliver power to one of the plurality of memory units through one of the plurality of processing units.

20. The electronic device of claim 15, further comprising a circuit structure comprising the optical channel and an electrical channel configured to transmit a second signal between two adjacent ones of the plurality of processing units.
